(19) United States
(12) Patent Application Publication
(10) Pub. No.: US 2026/0033281 A1
(43) Pub. Date: Jan. 29, 2026

(54) SEMICONDUCTOR MANUFACTURING OUTLIER DETECTION BASED ON MACHINE LEARNING

(71) Applicant: SKYWORKS SOLUTIONS, INC., Irvine, CA (US)

(72) Inventors: Cesar Mauricio PABLOS, Mexicali (MX); Zelman HERNANDEZ, Imperial, CA (US)

(21) Appl. No.: 19/279,416

(22) Filed: Jul. 24, 2025

Related U.S. Application Data
(60) Provisional application No. 63/676,194, filed on Jul. 26, 2024.

(51) Int. Cl. H01L 21/67; G06N 20/00; H01L 21/66

(52) U.S. Cl. CPC H01L 21/67288; G06N 20/00; H01L 22/12

(57) ABSTRACT

According to certain aspects, one or more processors can be configured to: determine a limit for detecting a lot associated with a specified product as an anomaly based on one or more machine learning models, the limit for detecting a lot associated with the specified product as an anomaly enabling a semiconductor manufacturing system to identify one or more defective lots at an earlier point in time than using another limit associated with the specified product determined based on a statistical method, and to identify one or more defective lots that do not satisfy the other limit based on the statistical method; in response to a failure rate of a first lot in connection with the parameter satisfying the limit, identify the first lot as an anomaly and automatically hold the first lot in order to address defects associated with the first lot in real time.

### CROSS-REFERENCE TO RELATED APPLICATION(S)

This application claims the benefit of U.S. Provisional Application No. 63/676,194, filed Jul. 26, 2024, entitled “SEMICONDUCTOR MANUFACTURING OUTLIER DETECTION BASED ON MACHINE LEARNING,” which is incorporated herein by reference in its entirety.

### BACKGROUND

### Field

The present disclosure generally relates to detecting outliers in semiconductor manufacturing, for example, relating to packaged electronic modules.

### Description of the Related Art

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. Various modules and/or components can be tested to detect any defects or anomalies, for example, during a semiconductor manufacturing process.

### SUMMARY

According to some implementations, the present disclosure relates to a semiconductor manufacturing system. The semiconductor manufacturing system can include a testing system configured to test a plurality of lots of radio-frequency modules in connection with a parameter associated with a radio-frequency module, the plurality of lots of radio-frequency modules associated with a specified product. The semiconductor manufacturing system can include one or more computing devices including one or more processors, individually or in combination, configured to: train one or more machine learning models based on training data relating to radio-frequency modules to identify a lot associated with the specified product as an anomaly in connection with the parameter; determine a limit for detecting a lot associated with the specified product as an anomaly based on the one or more machine learning models, the limit for detecting a lot associated with the specified product as an anomaly enabling the semiconductor manufacturing system to identify one or more defective lots at an earlier point in time than using another limit associated with the specified product determined based on a statistical method, and enabling the semiconductor manufacturing system to identify one or more defective lots that do not satisfy the other limit associated with the specified product determined based on the statistical method; determine a failure rate of a first lot in connection with the parameter; in response to the failure rate satisfying the limit, identify the first lot as an anomaly, the first lot identified as an anomaly at an earlier point in time than using the other limit based on the statistical method, or the first lot not identified as an anomaly using the other limit based on the statistical method; and in response to identifying the first lot as an anomaly, automatically hold the first lot in order to address defects associated with the first lot in real time, the defects not flagged using the other limit based on the statistical method.

In some examples, the parameter can be an electrical or electromagnetic parameter associated with the radio-frequency module. The parameter can include one or more of: a radio-frequency gain, a quiescent current, an insertion loss, or a leakage current. The limit based on the one or more machine learning models can be lower than the other limit associated with the specified product determined based on the statistical method, where the statistical method includes one or more of: six sigma, a statistical yield limit (SYL), or a statistical bin limit (SBL). The one or more processors, individually or in combination, can be further configured to, in response to the failure rate not satisfying the limit, identify the first lot as normal.

In certain examples, the one or more machine learning models can be trained using one or more of: a supervised machine learning algorithm or an unsupervised machine learning algorithm. In some examples, the one or more machine learning models can be based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In certain examples, the one or more machine learning models can include an ensemble machine learning model trained using an isolation forest algorithm and a kernel density estimation (KDE) algorithm. In some examples, the limit can be based on the ensemble machine learning model.

In some embodiments, the one or more processors, individually or in combination, can be further configured to: determine one or more hyperparameter values for training a machine learning model using an isolation forest algorithm; train a first machine learning model based on an isolation forest algorithm using training data associated with the specified product; determine a first outlier score threshold associated with the first machine learning model, the first outlier score threshold determined based on a bottom of a failure rate curve associated with the first machine learning model before reaching the other limit based on the statistical method; and determine a first limit based on the first machine learning model as a failure rate corresponding to the first outlier score threshold.

In certain embodiments, the one or more processors, individually or in combination, can be further configured to: determine one or more hyperparameter values for training a machine learning model using a kernel density estimation (KDE) algorithm; train a second machine learning model based on a KDE algorithm using training data associated with the specified product; determine a second outlier score threshold associated with the second machine learning model, the second outlier score threshold determined based on a bottom of a failure rate curve associated with the second machine learning model before reaching the other limit based on the statistical method; and determine a second limit based on the second machine learning model as a failure rate corresponding to the second outlier score threshold.

In some embodiments, the one or more processors, individually or in combination, can be further configured to: determine one or more hyperparameter values for training a machine learning model using a local outlier factor (LOF) algorithm; train a third machine learning model based on a LOF algorithm using training data associated with the specified product; determine a third outlier score threshold associated with the third machine learning model, the third outlier score threshold determined based on a bottom of a failure rate curve associated with the third machine learning model before reaching the other limit based on the statistical method; and determine a third limit based on the third machine learning model as a failure rate corresponding to the third outlier score threshold.

In some examples, the one or more processors, individually or in combination, can be further configured to determine the limit as an average or a median of the first limit based on the first machine learning model, the second limit based on the second machine learning model, and the third limit based on the third machine learning model. In other examples, the one or more processors, individually or in combination, can be further configured to determine the limit as an average of the first limit based on the first machine learning model and the second limit based on the second machine learning model.

In certain embodiments, the one or more processors, individually or in combination, can be further configured to: determine daily mean and variance values for a failure rate associated with the specified product for a specified period of time; train a machine learning model based on an isolation forest algorithm using the daily mean and variance values for the failure rate associated with the specified period of time; determine daily outlier scores associated with the specified product based on the machine learning model for the specified period of time; apply an exponentially weighted moving average to the daily outlier scores using a window of a plurality of days; determine an outlier score threshold for the exponentially weighted moving average; and set up an alarm that is used in response to a daily outlier score satisfying the outlier score threshold.

According to certain implementations, the present disclosure relates to a method for testing radio-frequency modules. The method can include providing a testing system configured to test a plurality of lots of radio-frequency modules in connection with a parameter associated with a radio-frequency module, the plurality of lots of radio-frequency modules associated with a specified product, the testing system included in a semiconductor manufacturing system. The method can include training, by one or more computing devices including one or more processors, one or more machine learning models based on training data relating to radio-frequency modules to identify a lot associated with the specified product as an anomaly in connection with the parameter. The method can include determining, by the one or more computing devices, a limit for detecting a lot associated with the specified product as an anomaly based on the one or more machine learning models, the limit for detecting a lot associated with the specified product as an anomaly enabling the semiconductor manufacturing system to identify one or more defective lots at an earlier point in time than using another limit associated with the specified product determined based on a statistical method, and enabling the semiconductor manufacturing system to identify one or more defective lots that do not satisfy the other limit associated with the specified product determined based on the statistical method. The method can include determining, by the one or more computing devices, a failure rate of a first lot in connection with the parameter. The method can include, in response to the failure rate satisfying the limit, identifying, by the one or more computing devices, the first lot as an anomaly, the first lot identified as an anomaly at an earlier point in time than using the other limit based on the statistical method, or the first lot not identified as an anomaly using the other limit based on the statistical method. The method can include, in response to identifying the first lot as an anomaly, automatically holding, by the one or more computing devices, the first lot in order to address defects associated with the first lot in real time, the defects not flagged using the other limit based on the statistical method.

In some examples, the parameter can be an electrical or electromagnetic parameter associated with the radio-frequency module. The parameter can include one or more of: a radio-frequency gain, a quiescent current, an insertion loss, or a leakage current. The limit based on the one or more machine learning models can be lower than the other limit associated with the specified product determined based on the statistical method, where the statistical method includes one or more of: six sigma, a statistical yield limit (SYL), or a statistical bin limit (SBL). The method can further include, in response to the failure rate not satisfying the limit, identifying the first lot as normal.

In certain examples, the one or more machine learning models can be trained using one or more of: a supervised machine learning algorithm or an unsupervised machine learning algorithm. In some examples, the one or more machine learning models can be based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In certain examples, the one or more machine learning models can include an ensemble machine learning model trained using an isolation forest algorithm and a kernel density estimation (KDE) algorithm. In some examples, the limit can be based on the ensemble machine learning model.

In some embodiments, the method can further include: determining, by the one or more computing devices, one or more hyperparameter values for training a machine learning model using an isolation forest algorithm; training, by the one or more computing devices, a first machine learning model based on an isolation forest algorithm using training data associated with the specified product; determining, by the one or more computing devices, a first outlier score threshold associated with the first machine learning model, the first outlier score threshold determined based on a bottom of a failure rate curve associated with the first machine learning model before reaching the other limit based on the statistical method; and determining, by the one or more computing devices, a first limit based on the first machine learning model as a failure rate corresponding to the first outlier score threshold.

In certain embodiments, the method can additionally include, determining, by the one or more computing devices, one or more hyperparameter values for training a machine learning model using a kernel density estimation (KDE) algorithm; training, by the one or more computing devices, a second machine learning model based on a KDE algorithm using training data associated with the specified product; determining, by the one or more computing devices, a second outlier score threshold associated with the second machine learning model, the second outlier score threshold determined based on a bottom of a failure rate curve associated with the second machine learning model before reaching the other limit based on the statistical method; and determining, by the one or more computing devices, a second limit based on the second machine learning model as a failure rate corresponding to the second outlier score threshold.

In some embodiments, determining, by the one or more computing devices, one or more hyperparameter values for training a machine learning model using a local outlier factor (LOF) algorithm; training, by the one or more computing devices, a third machine learning model based on a LOF algorithm using training data associated with the specified product; determining, by the one or more computing devices, a third outlier score threshold associated with the third machine learning model, the third outlier score threshold determined based on a bottom of a failure rate curve associated with the third machine learning model before reaching the other limit based on the statistical method; and determining, by the one or more computing devices, a third limit based on the third machine learning model as a failure rate corresponding to the third outlier score threshold.

In some examples, the method can additionally include determining, by the one or more computing devices, the limit as an average or a median of the first limit based on the first machine learning model, the second limit based on the second machine learning model, and the third limit based on the third machine learning model. In other examples, the method can additionally include determining, by the one or more computing devices, the limit as an average of the first limit based on the first machine learning model and the second limit based on the second machine learning model.

In certain embodiments, the method can further include: determining daily mean and variance values for a failure rate associated with the specified product for a specified period of time; training a machine learning model based on an isolation forest algorithm using the daily mean and variance values for the failure rate associated with the specified period of time; determining daily outlier scores associated with the specified product based on the machine learning model for the specified period of time; applying an exponentially weighted moving average to the daily outlier scores using a window of a plurality of days; determining an outlier score threshold for the exponentially weighted moving average; and setting up an alarm that is used in response to a daily outlier score satisfying the outlier score threshold.

According to some implementations, the present disclosure relates to a semiconductor manufacturing system. The semiconductor manufacturing system can include a testing system configured to test a plurality of lots of radio-frequency modules in connection with a parameter associated with a radio-frequency module. The semiconductor manufacturing system can include a computing device including one or more processors configured to: train one or more machine learning models based on training data relating to radio-frequency modules to identify a lot as an anomaly in connection with the parameter; determine a limit for detecting a lot as an anomaly based on the one or more machine learning models; determine a failure rate of a first lot in connection with the parameter; and in response to the failure rate satisfying the limit, identify the first lot as an anomaly.

In some examples, the parameter can be an electrical or electromagnetic parameter associated with the radio-frequency module. The parameter can include one or more of: a radio-frequency gain, a quiescent current, an insertion loss, or a leakage current. The limit based on the one or more machine learning models can be lower than a limit determined based on a statistical method including one or more of: six sigma, a statistical yield limit (SYL), or a statistical bin limit (SBL). The one or more processors can be further configured to, in response to the failure rate not satisfying the limit, identify the first lot as normal. In certain examples, the one or more processors can be further configured to, in response to identifying the first lot as an anomaly, hold the first lot to address defects in the first lot.

In certain examples, the one or more machine learning models can be trained using one or more of: a supervised machine learning algorithm or an unsupervised machine learning algorithm. In some examples, the one or more machine learning models can be based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In certain examples, the one or more machine learning models can include an ensemble machine learning model trained using an isolation forest algorithm and a kernel density estimation (KDE) algorithm. In some examples, the limit can be based on the ensemble machine learning model.

According to certain implementations, the present disclosure relates to a method for testing radio-frequency modules. The method can include: providing a testing system configured to test a plurality of lots of radio-frequency modules in connection with a parameter associated with a radio-frequency module; training one or more machine learning models, by a computing device including one or more processors, based on training data relating to radio-frequency modules to identify a lot as an anomaly in connection with the parameter; determining, by the computing device, a limit for detecting a lot as an anomaly based on the one or more machine learning models; determining, by the computing device, a failure rate of a first lot in connection with the parameter; and in response to the failure rate satisfying the limit, identifying, by the computing device, the first lot as an anomaly.

In some examples, the parameter can be an electrical or electromagnetic parameter associated with the radio-frequency module. The parameter can include one or more of: a radio-frequency gain, a quiescent current, an insertion loss, or a leakage current. The limit based on the one or more machine learning models can be lower than a limit determined based on a statistical method including one or more of: six sigma, a statistical yield limit (SYL), or a statistical bin limit (SBL). The method can further include, in response to the failure rate not satisfying the limit, identifying the first lot as normal. In certain examples, the method can further include, in response to identifying the first lot as an anomaly, holding the first lot to address defects in the first lot.

In certain examples, the one or more machine learning models can be trained using one or more of: a supervised machine learning algorithm or an unsupervised machine learning algorithm. In some examples, the one or more machine learning models can be based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In certain examples, the one or more machine learning models can include an ensemble machine learning model trained using an isolation forest algorithm and a kernel density estimation (KDE) algorithm. In some examples, the limit can be based on the ensemble machine learning model.

### BRIEF DESCRIPTION OF THE DRAWINGS

FIG. 1 is a diagram illustrating a time plot of leakage failure percent per lot with a static Statistical Bin Limit (SBL), in accordance with one or more embodiments.

FIG. 2 is a diagram illustrating a leakage failure percent per lot distribution, in accordance with one or more embodiments.

FIG. 3 is a diagram illustrating a leakage failure percent per lot distribution bootstrapped, in accordance with one or more embodiments.

FIG. 4 is a diagram illustrating detection of anomalies based on machine learning, in accordance with one or more embodiments.

FIG. 5 is a diagram illustrating an example application of an isolation forest algorithm, in accordance with one or more embodiments.

FIGS. 6A-6D relate to machine learning models and prediction results using an isolation forest algorithm, in accordance with one or more embodiments.

FIG. 7 is a diagram illustrating an example application of a kernel density estimation algorithm, in accordance with one or more embodiments.

FIGS. 8A-8D relate to machine learning models and prediction results using a kernel density estimation algorithm, in accordance with one or more embodiments.

FIGS. 9A-9D relate to machine learning models and prediction results using a local outlier factor algorithm, in accordance with one or more embodiments.

FIG. 10A is a diagram illustrating a chart relating to exponentially weighted moving average (EWMA) and outlier scores, in accordance with one or more embodiments.

FIG. 10B is a diagram illustrating a chart relating to types of alarms in connection with EWMA, in accordance with one or more embodiments.

FIG. 11 shows a process that can be implemented to provide detection of anomalies based on machine learning as described herein, in accordance with one or more embodiments.

FIG. 12 shows a process that can be implemented to provide detection of anomalies based on machine learning as described herein, in accordance with one or more embodiments.

FIG. 13 illustrates an example computing device that can be used to implement detection of anomalies based on machine learning, in accordance with one or more embodiments.

FIG. 14 depicts an example wireless device having or utilizing one or more advantageous features described herein, in accordance with one or more embodiments.

### DETAILED DESCRIPTION

The headings provided herein, if any, are for convenience only and do not necessarily affect the scope or meaning of the claimed invention.

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. For example, a packaging substrate can be a printed circuit board (PCB). One or more components can be mounted on the upper side of the packaging substrate, and an upper overmold can be provided to encapsulate such components. One or more components may also be mounted on the lower side of the packaging substrate, and a lower overmold can be provided to encapsulate such components. In some embodiments, a packaged module can be a dual-sided module.

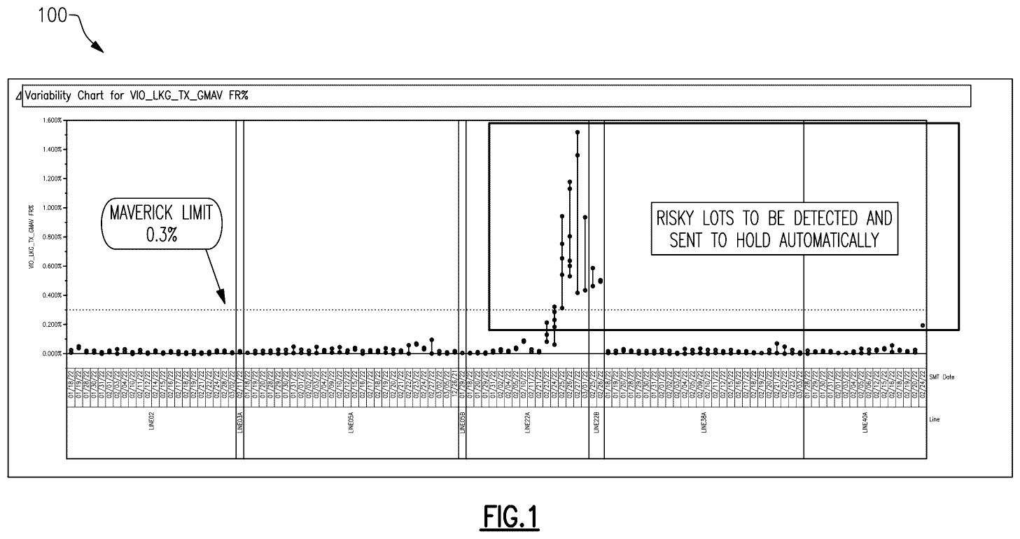

Various modules and/or components can be tested to detect any defects or anomalies, for example, during a semiconductor manufacturing process. Traditional statistical methods may be used to identify outliers, such as six (6) sigma, Statistical Yield Limits (SYLs), Statistical Bin Limits (SBLs), etc. For instance, a limit may be set for a failure rate (FR) for a lot above which tested modules and/or components are identified as being anomalies. In general, traditional statistical methods can be manual and need to be updated every few months for a product. In addition, some defects may occur even within acceptable limits set based on traditional statistical methods. In certain cases, a period of time may pass before the defects are flagged based on limits set by traditional statistical methods. As an example, the period of time may be one or more days. Accordingly, the present disclosure can provide detection of anomalies in a semiconductor manufacturing process based on machine learning techniques. Detection of anomalies based on machine learning techniques can identify outliers that are not detected using traditional statistical methods and/or that are detected at a later point in time using traditional statistical methods. Details relating to anomaly detection based on machine learning techniques are described below in connection with FIGS. 1-14.

FIGS. 1-3 relate to detection of anomalies based on traditional statistical methods. Traditional statistical methods may include one or more of 6-sigma, Statistical Yield Limits (SYLs), Statistical Bin Limits (SBLs), and other suitable methods. As an example, such statistical methods may be used to determine a limit for identifying a lot as an outlier in a semiconductor manufacturing process relating to modules and/or components. For instance, the limit may relate to a percentage of failed modules per lot. In some cases, the limit may be determined based on standard deviations. A lot not satisfying the limit may be identified as an outlier. An outlier may also be referred to as a maverick. A lot can include a plurality of modules, and a module can include one or more components. Examples of components may include semiconductor die, circuit elements such as discrete passive components, etc. Modules and/or components in a lot may be tested, and a failure rate percentage for the lot may be based on a number of modules and/or components that fail in the lot. A limit for identifying a lot as an outlier may be determined in connection with an appropriate parameter that is being tested for modules and/or components.

Various electrical and/or electromagnetic parameters relating to modules and/or components can be tested as appropriate. Examples of parameters can include RF gain, quiescent current, insertion loss, leakage current, etc. In some cases, such parameters may be critical to quality parameters that are correlated with RF and direct current (DC) components in modules. In certain embodiments, parameters such as RF gain, quiescent current, insertion loss, leakage current, etc. can test various aspects of modules and/or components including bias of amplifiers, amplification stages of amplifiers, silicon-on-insulator (SOI) devices, filtering, switching, transmit or receive chains, functionality of modules and/or components, etc. Any parameters that can be measured may be tested, depending on the embodiment.

FIG. 1 is a diagram 100 illustrating a time plot of leakage failure percent per lot with a static SBL. For instance, the diagram 100 is a variability plot showing production lines and associated dates on the X-axis and failure rate percentages for leakage current on the Y-axis. In the diagram 100, the limit for identifying a lot as an outlier can be the SBL, and the SBL for a failure rate for a lot is fixed or static and is set at 0.3%. Lots having failure rate percentages above the SBL can be identified as defective or outliers. In an example, leakage current may refer to a current consumed by SOI device(s) in modules when in standby. Components for modules may be mounted using surface mount technology (SMT) in production lines. Modules that are manufactured in a production environment can be managed by a production manufacturing execution system (MES) and can be tested in real time to detect and address any failures.

The diagram 100 shows failure rates per lot for production lines over time on different dates. For line 22A, deviations from median values begin appearing, but do not trigger an outlier lot based on the SBL. After a few days, the deviations from the median values pass the SBL and are flagged as outliers. As can be seen in the diagram 100, lots may start having defects that are still within the SBL, and the outlier detection may not be triggered until after a period of time passes, which is in this case several days. Being able to detect anomalies for lots that are still within the SBL set on traditional statistical methods can reduce anomalies in production and save time and resources. The outlier lots can be detected and sent to hold automatically to address the issues.

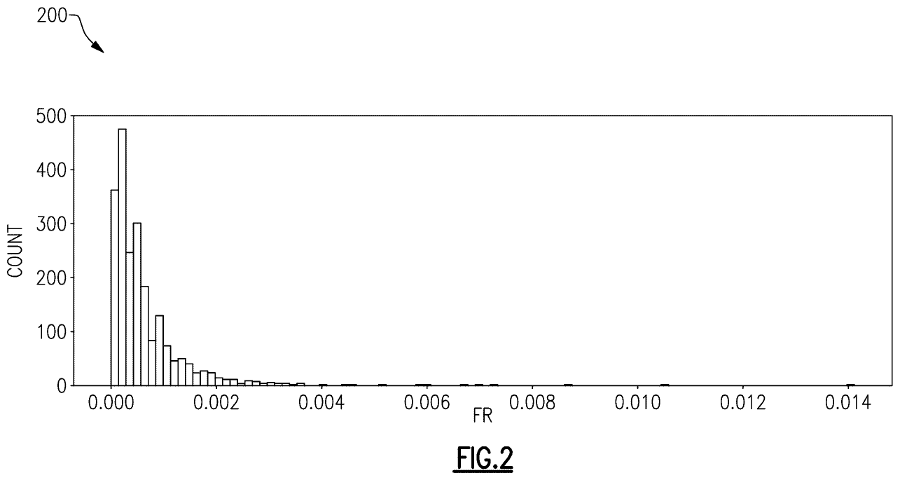

FIG. 2 is a diagram 200 illustrating a leakage failure percent per lot distribution. The diagram 200 shows failure rate percentages for leakage current on the X-axis and a count of lots on the Y-axis. For example, the diagram 200 shows lots on a regular distribution.

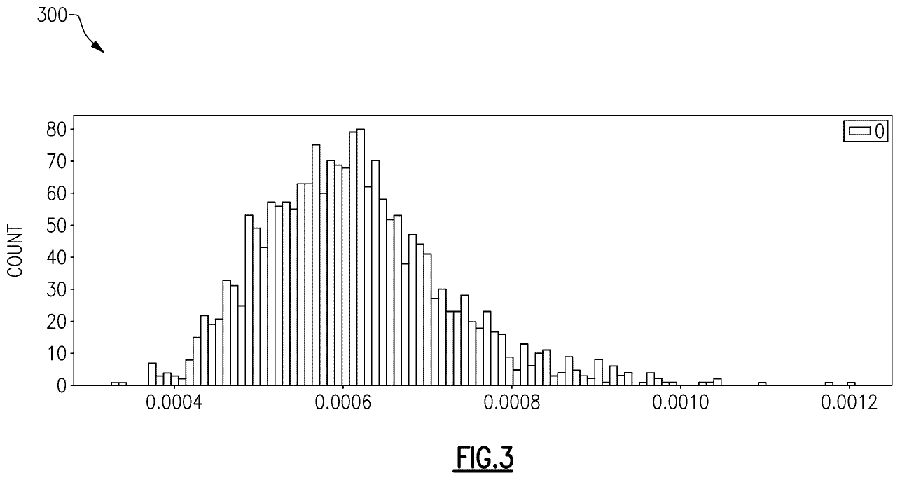

FIG. 3 is a diagram 300 illustrating a leakage failure percent per lot distribution bootstrapped. For instance, bootstrapping can use random sampling with replacement and assign measures of accuracy to sample estimates. Measures of accuracy may include bias, variance, confidence intervals, prediction error, etc. For example, the diagram 300 can show bootstrapped data for failure rate percentages for leakage current on the X-axis and a count relating to lots on the Y-axis.

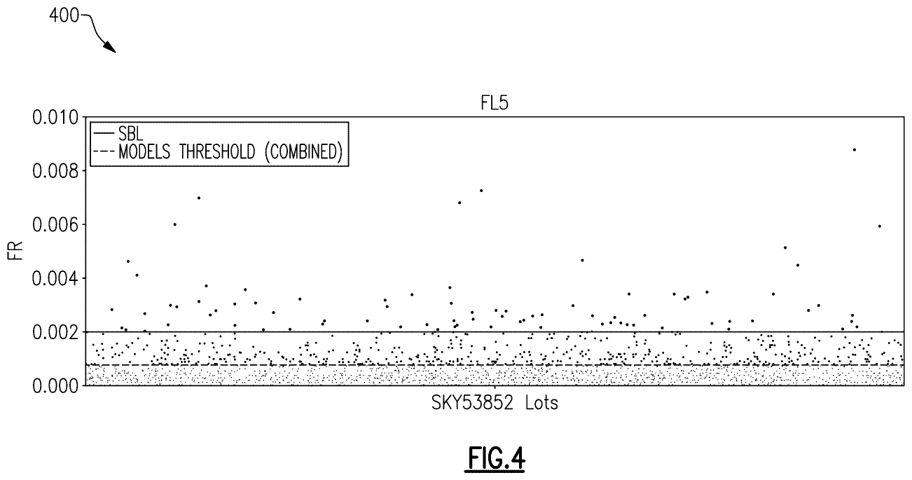

FIG. 4 is a diagram 400 illustrating detection of anomalies based on machine learning (ML). As described above, machine learning techniques can be used in detecting anomalies with respect to modules and/or components that are being tested in a production environment. The modules and/or components may be tested for a specified parameter(s). One or more machine learning models can be trained to determine whether a lot is an anomaly, for example, with respect to one or more parameters being tested. A machine learning model can be trained based on training data using a suitable machine learning algorithm. In some cases, machine learning algorithms that are used to train a machine learning model may be supervised or unsupervised. In supervised learning, the machine learning model can be trained on training data that is labeled. In unsupervised learning, the machine learning model can be trained on training data that is unlabeled. Training data can include examples and/or associated labels. For instance, an example can be represented as one or more features or a feature vector. In some embodiments, the training data may include information relating to a module lot, a wafer map, and/or a wafer probe, etc. A machine learning model can be trained based on various features in the training data using a machine learning algorithm. A machine learning model can detect patterns in the training data to make predictions relating to new input data.

A trained machine learning model can be applied to input data to provide an output that makes a prediction relating to the input data. For example, a trained machine learning model can make a prediction relating to an input lot and determine whether the lot is an anomaly or not. In some embodiments, the trained machine learning model may generate a score associated with an input lot, and an input lot having a score satisfying a threshold value may be identified as an anomaly, and an input lot having a score satisfying the threshold value may be identified as not an anomaly. A machine learning model may be retrained using new and/or updated training data. As an example, the training data can be updated to include results of predictions using the machine learning model.

In certain embodiments, one or more machine learning models can be trained to classify lots as anomalies or not anomalies. A machine learning model may be trained based on labeled or unlabeled training data, depending on the type of machine learning algorithm (e.g., supervised or unsupervised). Labeled training data can include a classification of whether a lot is an anomaly or not. Unlabeled training data may not include a classification of whether a lot is an anomaly or not. The trained machine learning model can make a prediction relating to an input lot and classify whether the lot is an anomaly or not. In some cases, the trained machine learning model may generate a score associated with an input lot, and an input lot can be classified as an anomaly or not an anomaly depending on whether the score satisfies a threshold value.

Various machine learning algorithms may be used as appropriate. Machine learning algorithms can include supervised, unsupervised, semi-supervised, reinforcement algorithms, etc. Examples of machine learning algorithms and/or related techniques can include isolation forest, kernel density estimation (KDE), local outlier factor (LOF), exponentially weighted moving average (EWMA), etc. Detection of anomalies may be based on a single machine learning model. In some embodiments, detection of anomalies can be based on an ensemble model. An ensemble model may combine or utilize two or more machine learning models. For instance, each machine learning model can be trained using a different machine learning algorithm and can be combined to make a prediction for new data. In an example, an output of a first machine learning model trained using a first algorithm and an output of a second machine learning model trained using a second algorithm can be averaged. In certain embodiments, machine learning models may be trained using Python. For instance, SciKit-Learn tool may be used. Detection of anomalies based on machine learning models may be implemented in connection with or integrated into a production MES.

A trained machine learning model can determine whether a lot is an anomaly or not, and a limit for identifying a lot as an anomaly. The limit for identifying a lot as an anomaly can be associated with a parameter being tested. For example, the limit for identifying a lot as an anomaly can be the SBL, and the SBL can be determined based on the trained machine learning model. The SBL determined based on the machine learning model may be lower than the SBL determined based on traditional statistical methods. In this way, the limit for identifying a lot as an anomaly can be determined dynamically using machine learning techniques. The limit for identifying a lot may also be referred to as the machine learning rejection threshold. Lots over the machine learning rejection threshold may be rejected and put on hold to address issues. Analysis can be performed for lots on hold to determine causes of defects, for example, in connection with failed modules and/or components.

To facilitate discussion, machine learning models may also be referred to as models. Machine learning models may be evaluated to determine prediction performance. If needed, machine learning models can be retrained. Hyperparameters relating to the machine learning models may be tuned or adjusted as appropriate. For example, hyperparameters can control the learning process. If anomaly detection involves different products, one or more machine learning models may be trained for each of the different products.

In the example of FIG. 4, an ensemble machine learning model is trained to determine whether a lot is an anomaly or not. A limit for identifying lots as anomalies may be determined based on the ensemble machine learning model. The limit can relate to a failure rate percentage for a lot with respect to a specified test parameter. For example, a first machine learning model can use an isolation forest algorithm, and a second machine learning model can use a KDE algorithm. Each machine learning model may be trained separately based on respective training data. Training data can include examples with or without corresponding labels. The training data can include relevant information relating to tested modules and/or components, lots, testing conditions, etc. In some embodiments, the following table can represent first rows of a dataset containing the information of lot failure rates, where the machine learning algorithm may use the failure rate values as features for model training:

TABLE 1

| Lot | Failure Rate |
|---|---|
| 31795105.1 | 0.00510 |
| 31800369.1 | 0.00347 |
| 31800149.1 | 0.00321 |
| 31791701.1 | 0.00294 |
| 31809291.1 | 0.00238 |
| 31808152.1 | 0.00233 |
| 31810358.1 | 0.00228 |
| 31722321.1 | 0.00210 |
| 31744710.1 | 0.00199 |
| 31826537.1 | 0.00175 |
| 31801492.1 | 0.00174 |

A limit for identifying a lot as an anomaly can be determined based on each machine learning model. For instance, the limit determined based on the first machine learning model trained using the isolation forest algorithm and the limit determined based on the second machine learning model trained using the KDE algorithm can be averaged to determine a combined limit for identifying a lot as an anomaly. A lot that has a failure rate percentage above the combined limit can be identified as an anomaly. Lots over the combined limit may be rejected and put on hold to address issues.

According to certain aspects, an isolation forest algorithm may use binary trees to detect anomalies. An isolation forest algorithm can use random forests and isolate samples by randomly selecting a feature and then randomly selecting a split value between maximum and minimum values of the selected feature. Recursive partitioning may be represented by a tree structure, and the number of splits needed to isolate a sample can be equivalent to the path length from the root node to the terminating node. The path length averaged over a forest of such random trees can be a measure of normality and the decision function. Random partitioning can produce generally shorter paths for anomalies. When a forest of random trees produces shorter path lengths for particular samples, such samples are likely to be anomalies. According to some aspects, a KDE algorithm may apply kernel smoothing for probability density estimation. For example, a KDE algorithm can use a nonparametric model to estimate the probability density function of a random variable based on kernels as weights. A kernel may be given by a nonnegative function and controlled by a smoothing parameter called a bandwidth.

In FIG. 4, the diagram 400 shows data results after machine learning and plot with model threshold. The diagram 400 shows lots on the X-axis and failure rate percentages for leakage current on the Y-axis. Lots are represented as dots. In the example of FIG. 4, the SBL determined based on traditional statistical methods is 0.2%. The SBL determined based on the isolation forest machine learning model is about 0.07% and the KDE machine learning model is about 0.1%. The SBL determined based on the isolation forest machine learning model and the KDE machine learning model is less than 0.1% (e.g., an average of the SBL based on each machine learning model). Large dots represent lots identified as anomalies based on the traditional SBL. For example, the large dots appear above the traditional SBL. Medium dots represent lots identified as anomalies based on the machine learning SBL. For example, the medium dots appear between the traditional SBL and the machine learning SBL. Small dots represent lots that are normal. For example, the small dots appear below the machine learning SBL. The number of lots detected as anomalies based on the isolation forest machine learning model is 782. The number of lots detected as anomalies based on the KDE machine learning model is 197. Almost 1,000 lots are additionally identified as anomalies using the SBL determined based on machine learning models. Details relating to anomaly detection based on machine learning models are described for illustrative purposes, and many variations are possible.

Traditional statistical methods can involve manual calculations, for example, using central tendency statistical analysis. While the traditional statistical methods can be simple and familiar to many people, the traditional statistical methods may have some limitations, such as being time-consuming, being prone to errors, or not being able to handle complex or large-scale problems. Machine learning based detection can use machine learning algorithms and data to learn from patterns and make predictions/decisions finding abnormal data points or clusters. Machine learning based detection can be fast, accurate, and adaptable to changing situations. Use of various computing resources can accommodate large-scale data and computational complexities. Cloud computing may also be used to provide on-demand computing resources and services and can facilitate flexibility, scalability, and cost-effectiveness in implementing machine learning based detection.

Machine learning based detection can automate various aspects of identifying outlier lots and can be used with various parameters relating to modules and/or components. Machine learning based detection can be implemented in a production environment to catch defects and address problems in real time. Machine learning based detection may also be applied to detect defects in packaging substrates, such as PCBs, from packaging substrate manufacturers. In certain embodiments, commonalities may be determined between lots identified as outliers and other lots that are not identified as outliers in order to examine a possibility of the other lots having a risk of being outliers. For instance, the other lots may be produced using the same line in the production environment. In certain embodiments, machine learning based detection may also be applied to groups of modules and/or components other than lots.

In this manner, detection of anomalies based on machine learning techniques can improve testing and identifying outlier lots in a semiconductor manufacturing process. For instance, machine learning based detection can identify outlier lots that may be within acceptable limits based on traditional statistical methods and not be detected. In some cases, machine learning based detection can also identify outliers at an earlier point in time compared to traditional statistical methods. Problematic lots can be put on hold and analyzed in real time to address defects. Accordingly, performance and reliability of modules and/or components can be improved using machine learning based detection.

### Example Implementations Relating to Anomaly Detection Based on Machine Learning

Certain implementations for anomaly detection based on machine learning techniques are described below. The example implementations are provided for illustrative purposes and should not be construed to limit the scope of the invention. Many variations are possible.

In some embodiments, one or more machine learning models may be trained using different machine learning algorithms. Each trained model can be evaluated to determine its performance. The results from various models may be compared and/or combined for better prediction results. For instance, an average or a median may be determined for outputs from different models. In certain cases, various machine learning algorithms and/or related techniques may be used together. One or more machine learning models may be trained for each product for which machine learning techniques are being applied. For example, different products may have different characteristics with respect to anomaly detection.

### Model Evaluation

In some embodiments, detection performance of machine learning models can be visualized using a confusion matrix that compares obtained detections with the ground truth as follows. For example, the ground truth can indicate actual values.

TABLE 2

| | Predicted Positive | Predicted Negative |
|---|---|---|
| Actual Positive | True Positive (TP) | False Negative (FN) |
| Actual Negative | False Positive (FP) | True Negative (TN) |

Each term in the matrix can represent the following:
True Positive (TP): The model correctly predicted the positive class.
True Negative (TN): The model correctly predicted the negative class.
False Positive (FP): The model incorrectly predicted the positive class (a “Type I error”).
False Negative (FN): The model incorrectly predicted the negative class (a “Type II error”).

From the above information, the following metrics can be calculated:
Recall (also known as Sensitivity): Explains the proportion of actual positives that was identified correctly:

$$Recall = \frac{TP}{TP + FN} \qquad ( 1 )$$

Precision: Explains what proportion of positive identifications was correct:

$$Precision = \frac{TP}{TP + FP} \qquad ( 2 )$$

Accuracy: The ratio of correctly predicted observations to the total observations:

$$Accuracy = \frac{TP + TN}{TP + FP + FN + TN} \qquad ( 3 )$$

In an imbalanced dataset, where the distribution of classes is skewed, it is possible to achieve high accuracy scores even with random predictions. For example, in a dataset where 90% of the instances belong to a positive class and only 10% belong to a negative class, a model that always predicts the positive class would still have an accuracy of 90%.

F1 Score: The weighted average of Precision and Recall. Therefore, this score takes both false positives and false negatives into account. The formula is:

$$F 1 = 2 \times \frac{( Recall \times Precsion )}{Recall + Precision} \qquad ( 4 )$$

F1 Score becomes 1 only when precision and recall are both 1. F1 score becomes high only when both precision and recall are high. F1 score is the harmonic mean of precision and recall and can be a better measure than accuracy for imbalanced datasets.

### Isolation Forest

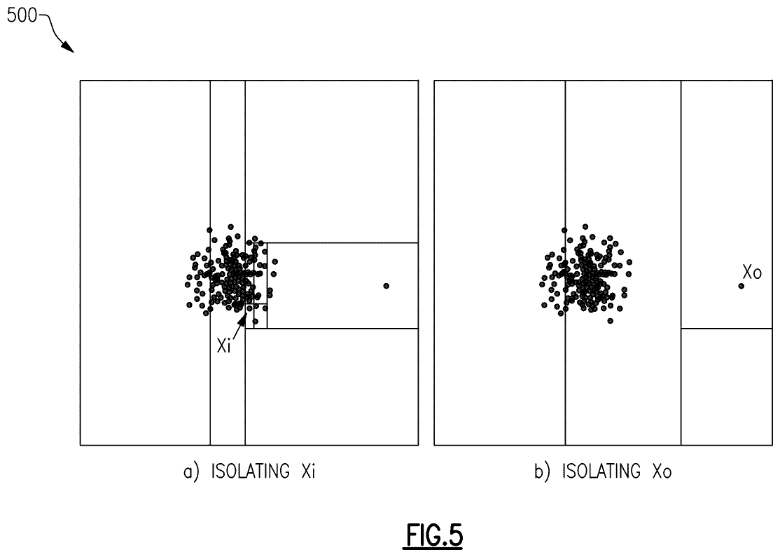

According to certain aspects, isolation forest can be a widely used machine learning algorithm for anomaly detection. Isolation forest can operate by generating numerous decision trees. Each tree can be created by choosing a feature at random and then picking a random split value that lies between the maximum and minimum values of that feature. This procedure can be carried out repeatedly until every data point has been isolated. For each data point, a path length can be determined based on the number of decisions made. Anomalies are then pinpointed by locating the data points with the shortest path lengths. Isolation forest can be widely used due to its low computational complexity, making it well-suited for processing large datasets and has found applications in various fields such as cybersecurity, finance, and medical research. Additionally, isolation forest does not require any previous data normalization or distribution adjustment, simplifying its implementation. FIG. 5 is a diagram 500 illustrating an example application of an isolation forest algorithm. The left portion (a) of the diagram 500 shows creating trees to isolate xᵢ, and the right portion (b) of the diagram 500 shows creating trees to isolate x₀.

### Hyperparameter Optimization

The contamination hyperparameter can determine the proportion of outliers in the dataset and is often adjusted. However, estimating the number of outliers can be challenging. One approach is to set a threshold by analyzing the Outlier Score (OS) behavior within the dataset.

The number of decision trees that compose the isolation forest ensemble can be another important hyperparameter. The number of decision trees may generally be set to 100. However, adjusting this value can improve the performance of the model.

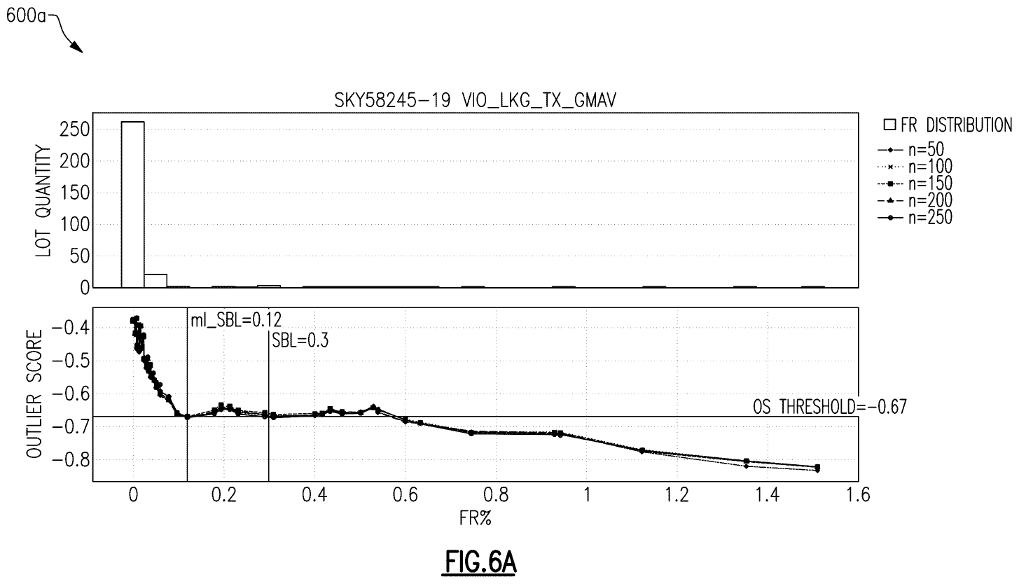

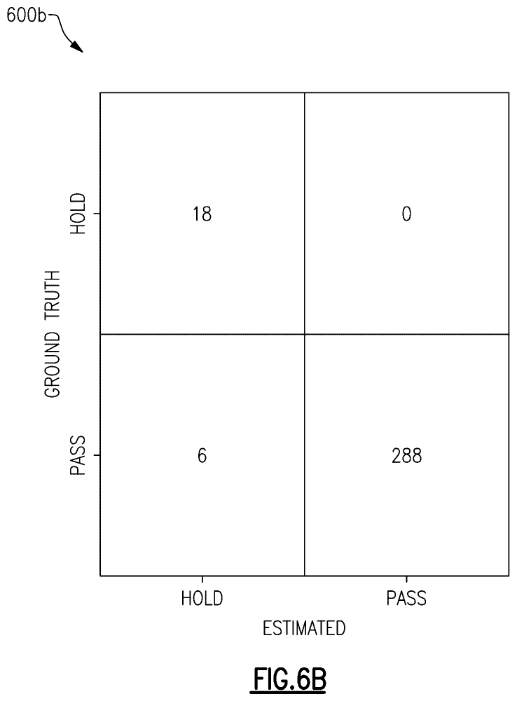

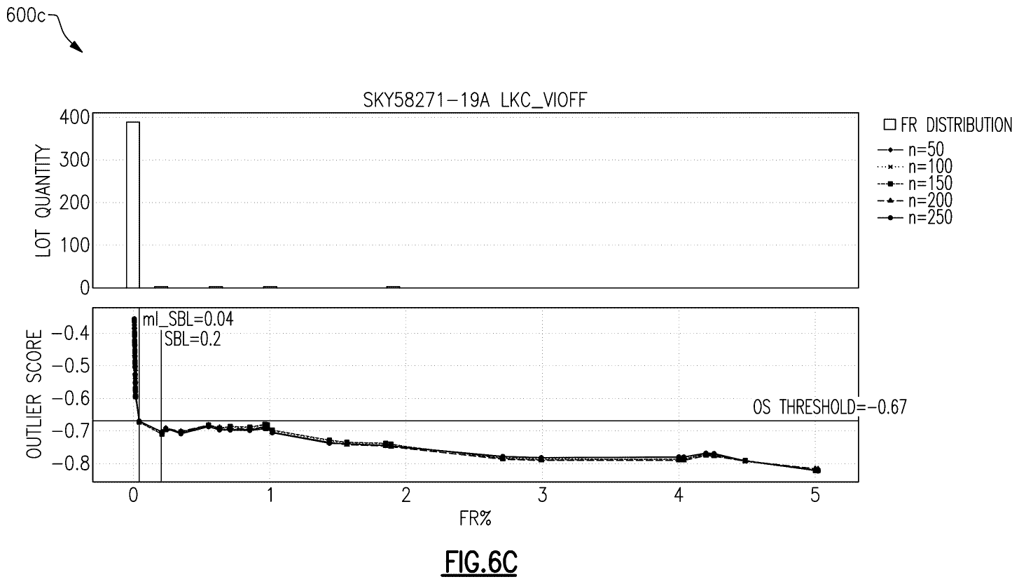

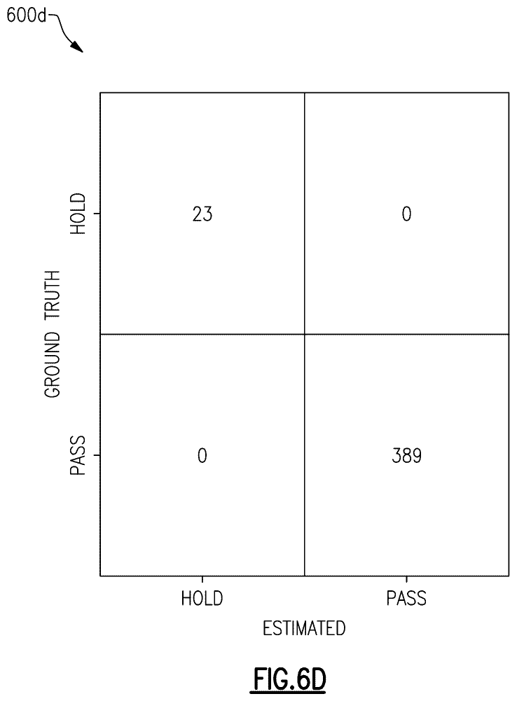

FIGS. 6A-6D relate to machine learning prediction results using an isolation forest algorithm. In certain implementations, in order to find an optimal OS threshold and number of decision trees for the isolation forest model, two datasets were used. The first dataset, SKY58245-19 VIO_LKG_TX_GMAV, can include FR values for lots belonging to part number SKY58245-19 and failure mode VIO_LKG_TX_GMAV. The second dataset, SKY58271-19A LKC_VIOFF, can include FR values for lots belonging to part number SKY58271-19A and test parameter LKC_VIOFF.

FIG. 6A is a diagram 600a illustrating charts relating to the first dataset, SKY58245-19 VIO_LKG_TX_GMAV. The top chart relates to FR distribution, and shows FR percentage on the X-axis and lot quantity on the Y-axis. The bottom chart relates to the OS, and shows FR percentage on the X-axis and the OS on the Y-axis. In the example of FIG. 6A, the OS threshold can be set at −0.67, which is where the bottom of the FR curve is found before reaching the actual SBL. This can mean that lots having an FR higher than 0.12 (ML SBL) will be rejected by machine learning. According to certain aspects, the SBL determined based on machine learning techniques may be referred to as the ML SBL, and the SBL determined without machine learning techniques, for example, traditional statistical methods, may be referred to as the original or actual SBL or simply the SBL. In the diagram 600a, n represents the number of decision trees, and it can be seen that the number of decision trees may not have a meaningful effect on the model behavior.

FIG. 6B is a diagram 600b illustrating a confusion matrix corresponding to the diagram 600a in FIG. 6A. In the diagram 600b, the model is over-rejecting 6 lots that were originally considered good, meaning these lots were above the ML SBL and below the original SBL. Accordingly, the model has a recall of 1.0, meaning the model was able to find all originally rejected lots. The model has a precision of 0.75 since the model rejected 6 more lots than was originally rejected by the SBL. The model has an F1 score of 0.85.

FIG. 6C is a diagram 600c illustrating charts relating to the second dataset, SKY58271-19A LKC_VIOFF. The top chart relates to FR distribution, and shows FR percentage on the X-axis and lot quantity on the Y-axis. The bottom chart relates to the OS, and shows FR percentage on the X-axis and the OS on the Y-axis. The same OS threshold (e.g., −0.67) used above for the first dataset can be used for the second dataset. Although a difference of 0.16% exists for the ML SBL and the actual SBL, no FR exists within this range. Furthermore, the outlier isolation threshold falls closer to the peak of the distribution.

FIG. 6D is a diagram 600d illustrating a confusion matrix corresponding to the diagram 600c in FIG. 6C. In the diagram 600d, the model coincides with the ground truth with an F1 score of 1.0.

### Kernel Density Estimation

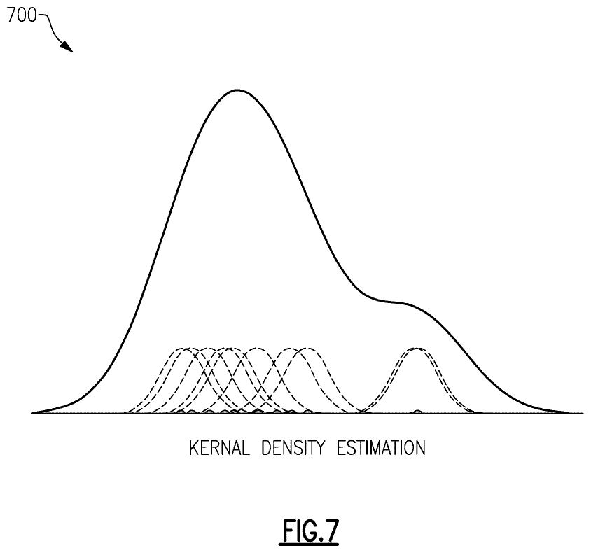

According to certain aspects, kernel density estimation (KDE) can be another method for finding outliers in a data distribution. KDE can work by placing a kernel (e.g., being a distribution shape, such as a bell curve) on each data point. The height of the kernel can be affected by the density of data points around that area. By summing up all the kernels, KDE can produce a smooth estimate of the data density function. As such, high density regions can correspond to the core of the data distribution. Points that fall into low-density regions can therefore be considered outliers or anomalies. FIG. 7 is a diagram 700 illustrating an example application of a kernel density estimation algorithm.

Like isolation forest, a threshold to systematically identify outliers can be required, so data points that have a density estimate below a given value can be classified as outliers. This threshold is generally estimated based on domain knowledge or by statistical criteria.

### Hyperparameter Optimization

In some embodiments, finding the kernel and the kernel bandwidth (e.g., the width of the kernel) can be done through testing every combination and calculating the log-likelihood of the data under the model. The log-likelihood can be a measure of how well a statistical model predicts a set of observations. For instance, this process can be done using the SciKit-Learn GridSearchCV tool for gaussian, linear, exponential, and epanechnikov kernels with bandwidths from 0.02 to 1.0 in steps of 0.02. Additionally, data can be standardized with z-score to improve the model predictive performance, where z-score is a statistical measurement that describes the relationship of a value to the mean in terms of standard deviations. In mathematical terms, the z-score can be calculated by the following formula:

$$Z = \frac{( X - μ )}{σ} \qquad ( 5 )$$

After conducting a grid search, optimal combinations for each of the previously tested two datasets were determined as follows:

TABLE 3

| Dataset | Kernel | Bandwidth |
|---|---|---|
| SKY58245-19 VIO_LKG_TX_GMAV | Exponential | 0.18 |
| SKY58271-19A LKC_VIOFF | Exponential | 0.2 |

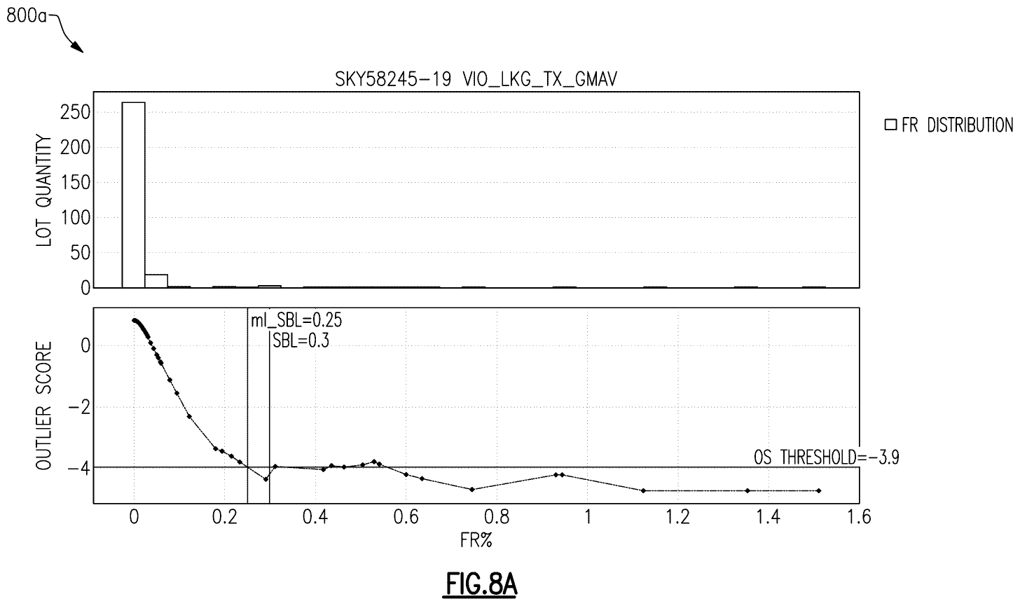

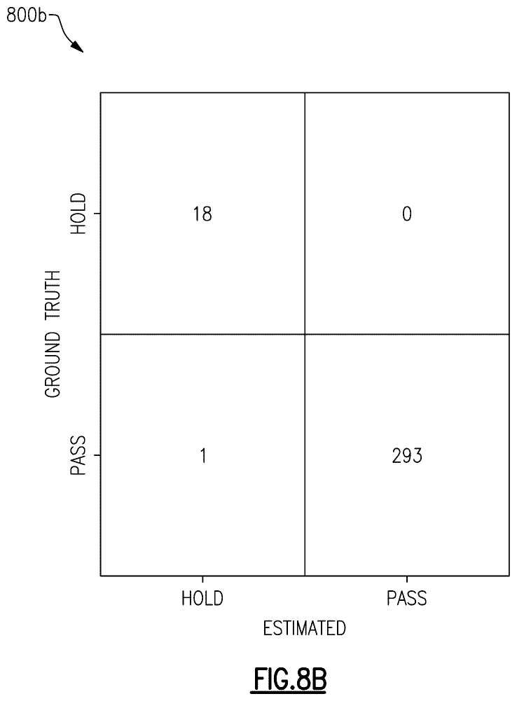

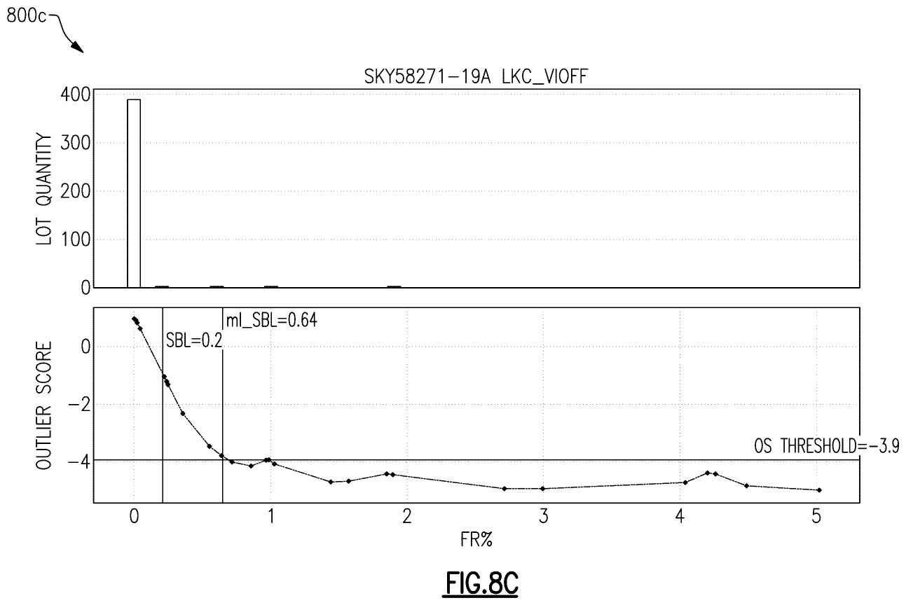

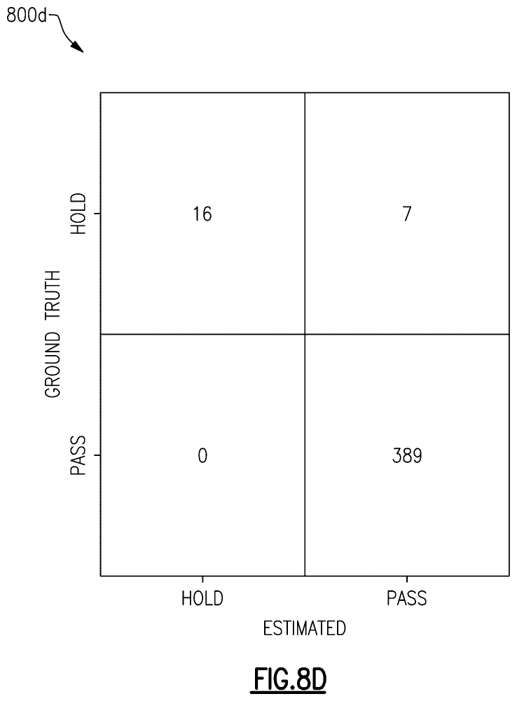

FIG. 8A-8D relate to machine learning prediction results using a kernel density estimation algorithm. To determine the OS threshold, an analysis of the model response to each of the datasets was conducted. For example, applying the same method used for isolation forest for SKY58245-19 VIO_LKG_TX_GMAV, the OS threshold can be roughly estimated at −3.9, which sets the ML SBL at 0.25.

FIG. 8A is a diagram 800a illustrating charts relating to the first dataset, SKY58245-19 VIO_LKG_TX_GMAV. The top chart relates to FR distribution, and shows FR percentage on the X-axis and lot quantity on the Y-axis. The bottom chart relates to the OS, and shows FR percentage on the X-axis and the OS on the Y-axis. FIG. 8B is a diagram 800b illustrating a confusion matrix corresponding to the diagram 800a in FIG. 8A. As shown in the diagram 800b, the model has a recall of 1.0 and a precision of 0.94, resulting in an F1 score of 0.97.

FIG. 8C is a diagram 800c illustrating charts relating to the second dataset, SKY58271-19A LKC_VIOFF. The top chart relates to FR distribution, and shows FR percentage on the X-axis and lot quantity on the Y-axis. The bottom chart relates to the OS, and shows FR percentage on the X-axis and the OS on the Y-axis. FIG. 8D is a diagram 800d illustrating a confusion matrix corresponding to the diagram 800c in FIG. 8C. In the diagram 800c, the ML SBL is estimated at a higher value than the original SBL, being at 0.64. In the diagram 800d, the model has a recall of 0.69, a precision of 1.0, and an F1 score of 0.82.

### Local Outlier Factor

According to certain aspects, a local outlier factor may be a machine learning algorithm used for anomaly detection. For each data point in the dataset, a measure of its local density can be calculated by looking at the distances between a point and its nearest neighbors. The basic idea can be that points that are part of a dense cluster will have their nearest neighbors relatively close, while outliers will have their nearest neighbors farther away. The local density of a point can then be compared to the density of its neighbors. This comparison is quantified as a score known as the Local Outlier Factor (LOF), which serves as the OS to identify outlying points.

The local density of a point is obtained by defining the distance between the kth nearest neighbor and a point, also known as the k-distance:

$$kdist ( x ) = dist ( x , kth nearest neighbor ) \qquad ( 6 )$$

The k-distance is then used to calculate the reachability distance (RD). This is defined by the maximum distance between two points and the k-distance of that point. For example, to find the reachability distance from point a to point b, the distance between these points can be compared with the k-distance of a, and the maximum distance can be determined as follows:

$$reach\_dist = max ( dist ( x , y ) , kdist ( x ) ) \qquad ( 7 )$$

Next, the local reachability density (Ird) can be the inverse of the average distance of each point within k-distance:

$${lrd}_{k} ( p ) = {( \frac{{\sum }_{o ∈ {N}_{k} ( p )} reach\_dist ( p , o )}{\vert {N}_{k} ( p ) \vert} )}^{- 1} \qquad ( 8 )$$

Finally, the LOF can be calculated by taking the ratio of the average of the Ird of k number of neighbors of a point and the Ird of a given point:

$${LOF}_{k} ( p ) = \frac{{\sum }_{o ∈ {N}_{k} ( p )} \frac{lrd ( o )}{ldr ( p )}}{\vert {N}_{k} ( p ) \vert} \qquad ( 9 )$$

### Hyperparameter Optimization

The parameter k can be adjusted to optimize the performance of the LOF model as the parameter can greatly influence the performance of the model. The parameter k can correspond to the number of neighbors to consider for each data point. The parameter k can be typically set to be greater than the minimum number of samples a cluster has to contain, such that other samples can be local outliers relative to this cluster, and smaller than the maximum number of close-by samples that can potentially be outliers. In practice, no such information is generally available, and common practice can be to set this parameter to 20. However, the optimal value of k can vary depending on the specific dataset.

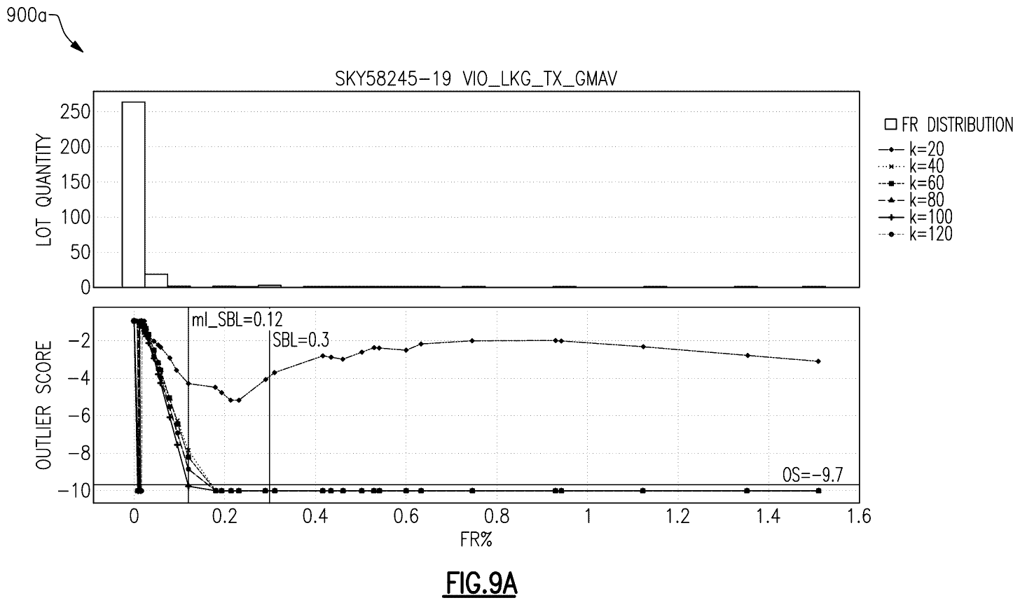

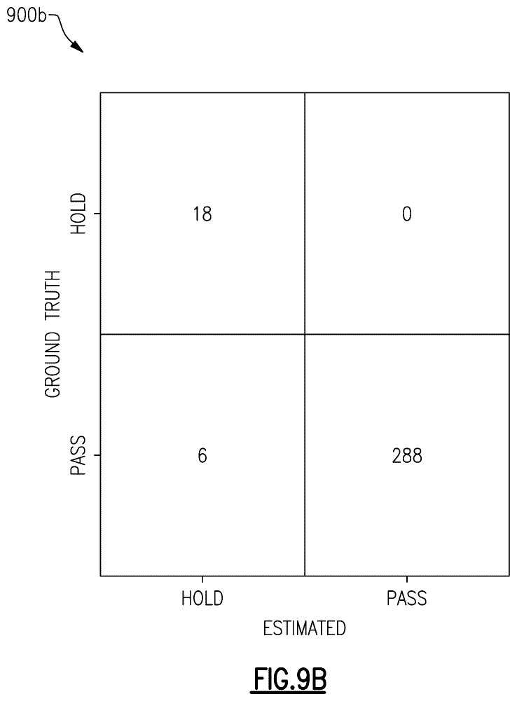

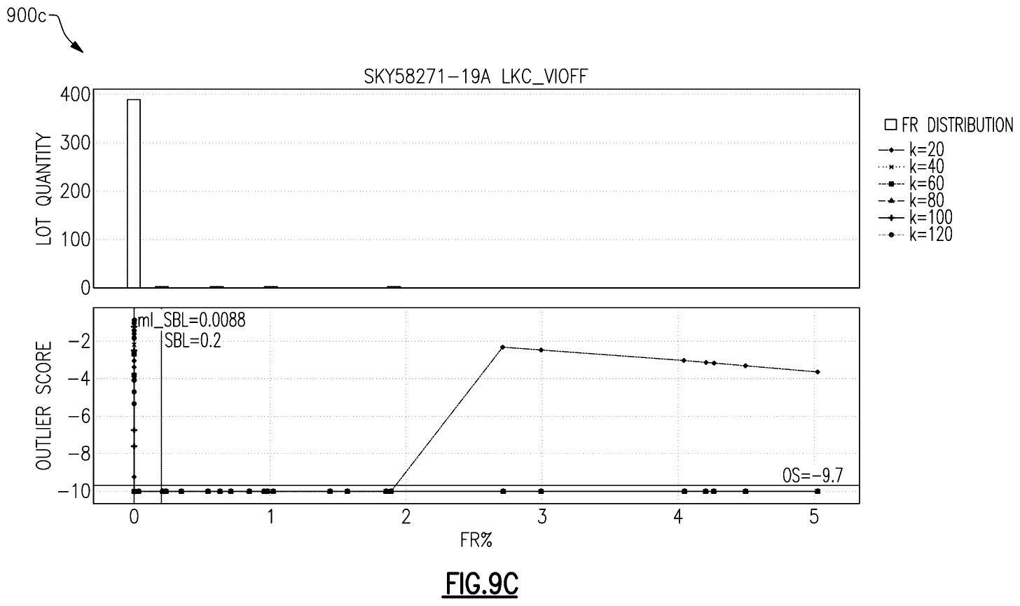

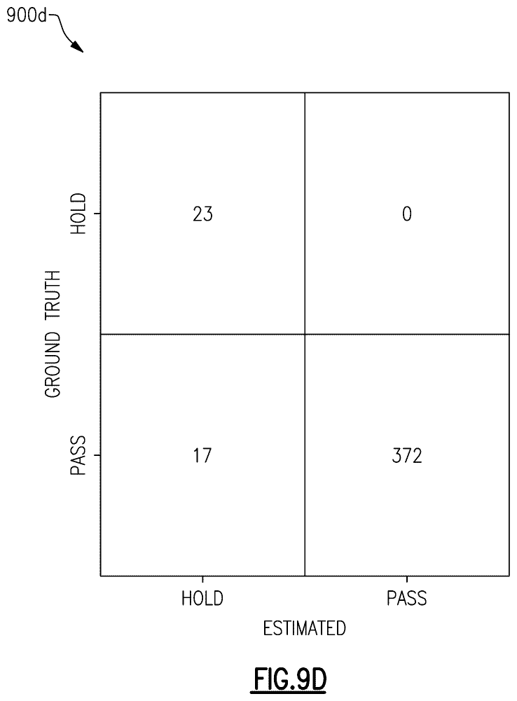

FIG. 9A is a diagram 900a illustrating charts relating to the first dataset, SKY58245-19 VIO_LKG_TX_GMAV. The top chart relates to FR distribution, and shows FR percentage on the X-axis and lot quantity on the Y-axis. The bottom chart relates to the OS, and shows FR percentage on the X-axis and the OS on the Y-axis. FIG. 9B is a diagram 900b illustrating a confusion matrix corresponding to the diagram 900a in FIG. 9A.

The LOF (e.g., OS on the Y-axis) is noisy for all values of k when data is close to 0. However, as the FR distances from 0, a gradual drop in the OS can be seen. This drop can become steeper for higher values of k. For example, the model becomes less tolerant to higher values of FR. For k=20, it can be seen that the model is more susceptible to clusters of FR data points. This could become an issue in practice where the model might fail to detect lots with an FR close to or higher than the actual SBL.

For this reason, the k value can be set to k=100, and the OS threshold can be set to −9.7, resulting in a ML SBL of 0.12. To solve the noise issue at FR values close to 0, the right tail of the distribution can be observed, meaning that values at the left of the FR median are not being considered for outlier detection.

Similar to isolation forest, the confusion matrix in the diagram 900b shows a recall of 1.0, a precision of 0.75, and an F1 Score of 0.85.

FIG. 9C is a diagram 900c illustrating charts relating to the second dataset, SKY58271-19A LKC_VIOFF. The top chart relates to FR distribution, and shows FR percentage on the X-axis and lot quantity on the Y-axis. The bottom chart relates to the OS, and shows FR percentage on the X-axis and the OS on the Y-axis. FIG. 9D is a diagram 900d illustrating a confusion matrix corresponding to the diagram 900c in FIG. 9C. The confusion matrix in the diagram 900d shows that the model has a recall of 1.0 and a precision of 0.575, resulting in an F1 score of 0.73.

### Combining Model Results

Results based on various machine learning models for each of the datasets can be summarized as follows:

TABLE 4

| | | | | |
|---|---|---|---|---|
| Model | ML SBL | Recall | Precision | F1 Score |

SKY58245-19 VIO_LKG_TX_GMAV (SBL = 0.3)

| | | | | |
|---|---|---|---|---|
| IF | 0.12 | 1.0 | 0.75 | 0.85 |
| KDE | 0.25 | 1.0 | 0.94 | 0.97 |
| LOF | 0.12 | 1.0 | 0.75 | 0.85 |

SKY58271-19A LKC_VIOFF (SBL = 0.2)

| | | | | |
|---|---|---|---|---|
| IF | 0.04 | 1.0 | 1.0 | 1.0 |
| KDE | 0.64 | 0.69 | 1.0 | 0.82 |
| LOF | 0.0088 | 1.0 | 0.575 | 0.73 |

While KDE had the best performance for the SKY58245-19 VIO_LKG_TX_GMAV dataset, a lower recall can be seen for the SKY58271-19A LKC_VIOFF dataset. Having a lower recall can mean potentially problematic lots are being neglected by the model. While a model might perform better in some situations, attention should be paid for this behavior, especially in an automatized production environment. Combining the model results may help alleviate an abrupt performance drop of a model from one dataset to another. For instance, one way to combine the model decisions is to calculate the median of the machine learning models.

By taking the median, lot detection results can be as follows:

TABLE 5

| | | | | |
|---|---|---|---|---|
| Model | ML SBL | Recall | Precision | F1 Score |

SKY58245-19 VIO_LKG_TX_GMAV (SBL = 0.3)

| | | | | |
|---|---|---|---|---|
| ML Median | 0.12 | 1.0 | 0.75 | 0.85 |

SKY58271-19A LKC_VIOFF (SBL = 0.2)

| | | | | |
|---|---|---|---|---|
| ML Median | 0.04 | 1.0 | 1.0 | 1.0 |

Although an F1 score drop can be seen for the first dataset as the result of a lower precision (e.g., more “passing” lots are rejected), the recall in the second dataset is improved, meaning that in this case problematic lots are not being overlooked.

### Exponentially Weighted Moving Average

According to certain aspects, exponentially weighted moving average (EWMA) may be used for anomaly detection. EWMA is a type of moving average that gives more weight to recent data and less weight to older data. EWMA can be used for time-series data analysis where recent trends may receive more importance.

For an example implementation, the daily mean and variance for FR were calculated for data starting from the beginning of April 2023 to the end of July 2023 for a test parameter belonging to part number 58292-16. Isolation forest was then applied to these features, resulting in a daily outlier score. EWMA was then applied using a 3-day and 5-day window to smooth the prediction data.

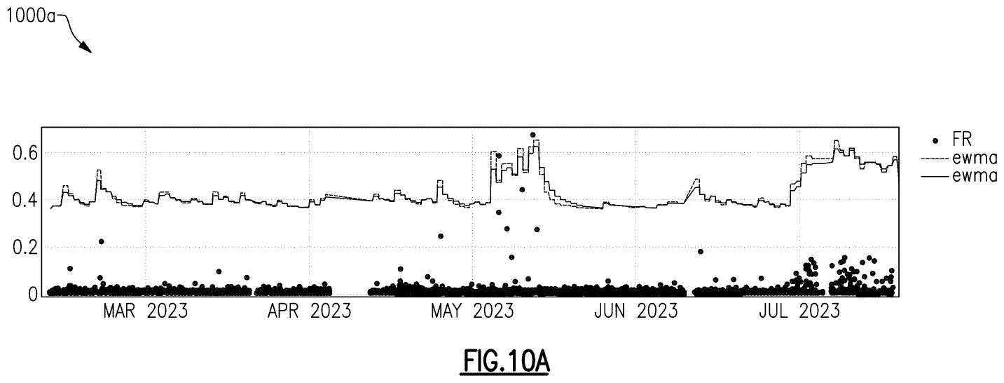

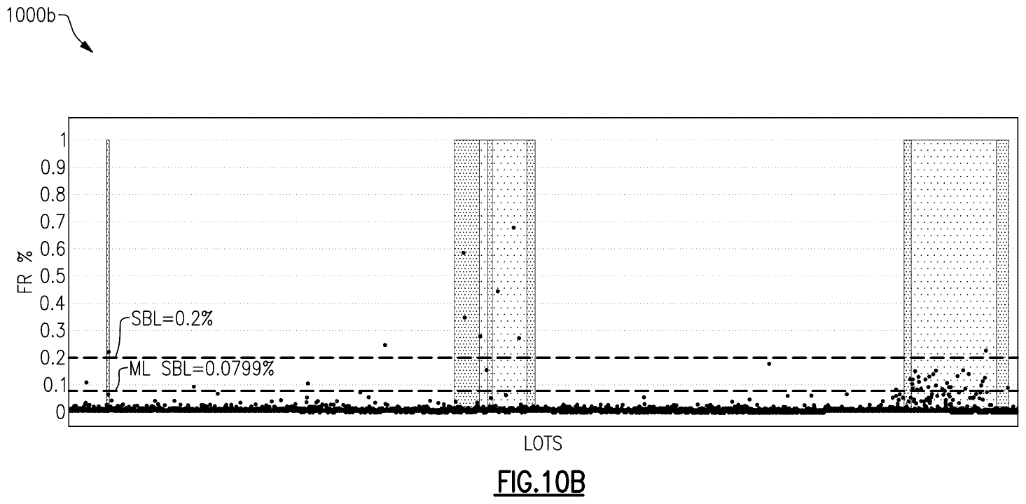

FIG. 10A is a diagram 1000a illustrating a chart relating to EWMA and outlier scores. For example, the diagram 1000a shows the outlier score for each EWMA window over the dataset.

Using the data relating to the diagram 1000a, a threshold can be set to alert whenever an abnormal behavior is being detected by the machine learning model. In an example, 2 types of alarms were used. FIG. 10B is a diagram 1000b illustrating a chart relating to the 2 types of alarms. The chart shows lots on the X-axis and FR percentage on the Y-axis. The ML SBL is set at 0.0799%, and the SBL is set at 0.2%. The first alarm is a yellow or “level 1” alarm, represented by a first dotted pattern (e.g., a narrow dot pattern), used whenever the outlier score given by the 3-day EWMA passes its OS threshold, and the second alarm is a red or “level 2” alarm, represented by a second dotted pattern (e.g., a wide dot pattern), used whenever the outlier score given by the 5-day EWMA passes its OS threshold.

In practice, the training window, for example, 6 months of data in the previous example, as well as the length of the EWMA windows can be adjusted to optimize the warning estimations. When the analysis is performed on a daily basis, this procedure can be implemented using a training window that corresponds to the most recent data, and considering only the warning level corresponding to the current day.

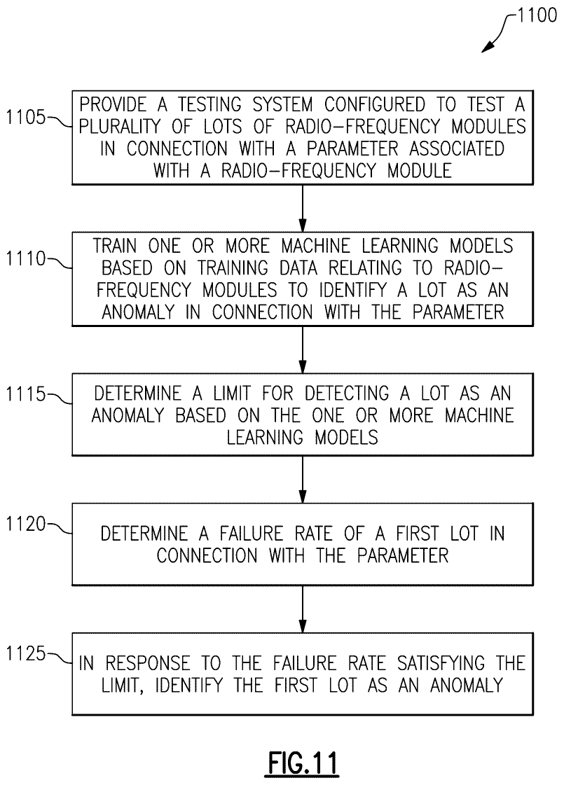

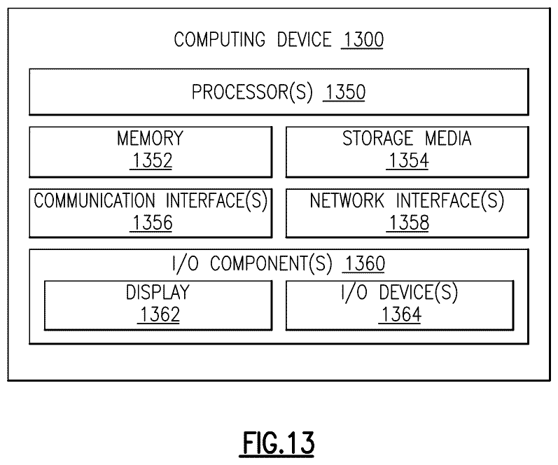

FIG. 11 shows a process 1100 that can be implemented to provide detection of anomalies based on machine learning as described herein. Certain details relating to the process 1100 are explained in more detail with respect to FIGS. 1-10. The process 1100 may be performed by a computing device comprising one or more processors or any other appropriate system or device. For example, the process 1100 can be performed by a computing device 1300 in FIG. 13. Depending on the embodiment, the process 1100 may include fewer or additional blocks, and the blocks may be performed in an order that is different from illustrated.

At block 1105, the process 1100 can provide a testing system configured to test a plurality of lots of radio-frequency modules in connection with a parameter associated with a radio-frequency module. The parameter can be an electrical or electromagnetic parameter associated with the radio-frequency module. In some embodiments, the parameter can include one or more of: a radio-frequency gain, a quiescent current, an insertion loss, or a leakage current.

At block 1110, the process 1100 can train one or more machine learning models based on training data relating to radio-frequency modules to identify a lot as an anomaly in connection with the parameter. In some embodiments, the one or more machine learning models are trained using one or more of: a supervised machine learning algorithm or an unsupervised machine learning algorithm. In certain embodiments, the one or more machine learning models are based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In some embodiments, the one or more machine learning models can include an ensemble machine learning model trained using an isolation forest algorithm and a kernel density estimation (KDE) algorithm.

At block 1115, the process 1100 can determine a limit for detecting a lot as an anomaly based on the one or more machine learning models. The limit based on the one or more machine learning models can be lower than a limit determined based on a statistical method including one or more of: six sigma, a statistical yield limit (SYL), or statistical bin limit (SBL). In some embodiments, the one or more machine learning models can include an ensemble machine learning model trained using an isolation forest algorithm and a kernel density estimation (KDE) algorithm. For example, the limit can be based on the ensemble machine learning model.

At block 1120, the process 1100 can determine a failure rate of a first lot in connection with the parameter. At block 1125, the process 1100 can, in response to the failure rate satisfying the limit, identify the first lot as an anomaly. Further, the process 1100 can, in response to identifying the first lot as an anomaly, hold the first lot to address defects in the first lot. The process 1100 can, in response to the failure rate not satisfying the limit, identify the first lot as normal.

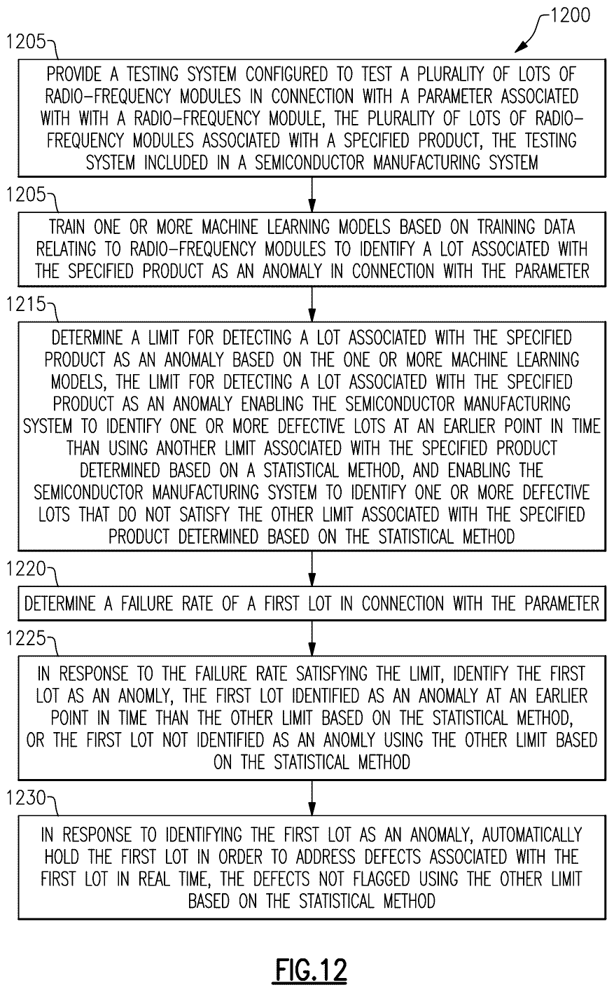

FIG. 12 shows a process 1200 that can be implemented to provide detection of anomalies based on machine learning as described herein. Certain details relating to the process 1200 are explained in more detail with respect to FIGS. 1-11. The process 1200 may be performed by a computing device comprising one or more processors or any other appropriate system or device. For example, the process 1200 can be performed by a computing device 1300 in FIG. 13. Depending on the embodiment, the process 1200 may include fewer or additional blocks, and the blocks may be performed in an order that is different from illustrated.

At block 1205, the process 1200 can provide a testing system configured to test a plurality of lots of radio-frequency modules in connection with a parameter associated with a radio-frequency module, where the plurality of lots of radio-frequency modules is associated with a specified product, and the testing system is included in a semiconductor manufacturing system. The parameter can be an electrical or electromagnetic parameter associated with the radio-frequency module. In some embodiments, the parameter can include one or more of: a radio-frequency gain, a quiescent current, an insertion loss, or a leakage current.

At block 1210, the process 1200 can train one or more machine learning models based on training data relating to radio-frequency modules to identify a lot associated with the specified product as an anomaly in connection with the parameter. In some embodiments, the one or more machine learning models are trained using one or more of: a supervised machine learning algorithm or an unsupervised machine learning algorithm. In certain embodiments, the one or more machine learning models are based on machine learning algorithms or techniques including one or more of: an isolation forest algorithm, a kernel density estimation (KDE) algorithm, a local outlier factor (LOF) algorithm, or an exponentially weighted moving average (EWMA) algorithm. In some embodiments, the one or more machine learning models can include an ensemble machine learning model trained using an isolation forest algorithm and a kernel density estimation (KDE) algorithm.

At block 1215, the process 1200 can determine a limit for detecting a lot associated with the specified product as an anomaly based on the one or more machine learning models, where the limit for detecting a lot associated with the specified product as an anomaly enables the semiconductor manufacturing system to identify one or more defective lots at an earlier point in time than using another limit associated with the specified product determined based on a statistical method, and enables the semiconductor manufacturing system to identify one or more defective lots that do not satisfy the other limit associated with the specified product determined based on the statistical method. The limit based on the one or more machine learning models can be lower than the other limit associated with the specified product determined based on the statistical method, where the statistical method includes one or more of: six sigma, a statistical yield limit (SYL), or a statistical bin limit (SBL). In some embodiments, the one or more machine learning models can include an ensemble machine learning model trained using an isolation forest algorithm and a kernel density estimation (KDE) algorithm. For example, the limit can be based on the ensemble machine learning model.

At block 1220, the process 1200 can determine a failure rate of a first lot in connection with the parameter.

At block 1225, the process 1200 can, in response to the failure rate satisfying the limit, identify the first lot as an anomaly, where the first lot is identified as an anomaly at an earlier point in time than using the other limit based on the statistical method, or where the first lot is not identified as an anomaly using the other limit based on the statistical method. The process 1200 can, in response to the failure rate not satisfying the limit, identify the first lot as normal.

At block 1230, the process 1200 can, in response to identifying the first lot as an anomaly, automatically hold the first lot in order to address defects associated with the first lot in real time, where the defects are not flagged using the other limit based on the statistical method.

In some embodiments, the process 1200 can determine one or more hyperparameter values for training a machine learning model using an isolation forest algorithm. The process 1200 can train a first machine learning model based on an isolation forest algorithm using training data associated with the specified product. The process 1200 can determine a first outlier score threshold associated with the first machine learning model, where the first outlier score threshold can be determined based on a bottom of a failure rate curve associated with the first machine learning model before reaching the other limit based on the statistical method. The process 1200 can determine a first limit based on the first machine learning model as a failure rate corresponding to the first outlier score threshold.

In certain embodiments, the process 1200 can determine one or more hyperparameter values for training a machine learning model using a kernel density estimation (KDE) algorithm. The process 1200 can train a second machine learning model based on a KDE algorithm using training data associated with the specified product. The process 1200 can determine a second outlier score threshold associated with the second machine learning model, where the second outlier score threshold can be determined based on a bottom of a failure rate curve associated with the second machine learning model before reaching the other limit based on the statistical method. The process 1200 can determine a second limit based on the second machine learning model as a failure rate corresponding to the second outlier score threshold.

In some embodiments, the process 1200 can determine one or more hyperparameter values for training a machine learning model using a local outlier factor (LOF) algorithm. The process 1200 can train a third machine learning model based on a LOF algorithm using training data associated with the specified product. The process 1200 can determine a third outlier score threshold associated with the third machine learning model, where the third outlier score threshold can be determined based on a bottom of a failure rate curve associated with the third machine learning model before reaching the other limit based on the statistical method. The process 1200 can determine a third limit based on the third machine learning model as a failure rate corresponding to the third outlier score threshold.

In certain embodiments, the process 1200 can determine the limit as an average or a median of the first limit based on the first machine learning model, the second limit based on the second machine learning model, and the third limit based on the third machine learning model. In some embodiments, the process 1200 can determine the limit as an average of the first limit based on the first machine learning model and the second limit based on the second machine learning model.

In some embodiments, the process 1200 can determine daily mean and variance values for a failure rate associated with the specified product for a specified period of time. The process 1200 can train a machine learning model based on an isolation forest algorithm using the daily mean and variance values for the failure rate associated with the specified period of time. In certain cases, machine learning algorithms other than isolation forest may be used. The process 1200 can determine daily outlier scores associated with the specified product based on the machine learning model for the specified period of time. The process 1200 can apply an exponentially weighted moving average to the daily outlier scores using a window of a plurality of days. The process 1200 can determine an outlier score threshold for the exponentially weighted moving average. The process 1200 can set up an alarm that is used in response to a daily outlier score satisfying the outlier score threshold. In some cases, multiple alarms can be used, for example, in connection with multiple windows.

In this manner, detection of outlier lots in semiconductor manufacturing can be improved based on machine learning to identify defective lots that may not be detected using a traditional SBL as well as identify defective lots at an earlier point in time to address defects in real time. Different products can have different characteristics, and an appropriate limit for determining whether a lot is an anomaly can be determined for each product. An optimal limit for determining whether a lot associated with a specified product is an anomaly can be determined based on training machine learning models using machine learning algorithms that are suitable for the specified product. Values for hyperparameters and other features can be selected and tuned as appropriate such that the machine learning models can provide desired prediction results for the specified product. One or more particular algorithms or machine learning models that work best for a specified product can be determined, and the limit for identifying whether a lot is an anomaly can be determined based on such algorithms or machine learning models. For example, models customized for each product can be trained and evaluated to determine the optimal limit. Since different products can have varying characteristics, for example, with respect to testing and anomaly detection, the algorithms or machine learning models that work best for each product can be different.

In some cases, multiple machine learning models can be trained for a product to determine which model provides the best prediction results. The limit for determining outlier lots can be determined for each machine learning model, for example, based on the failure rate curve. Each model can be evaluated based on various criteria, such as recall, precision, F1 score, etc. Some or all of the limits determined for the different models may be selected or combined to determine the overall limit. In certain cases, a median or an average of the limits based on the different models can be used as the overall limit for the product. In some cases, the overall limit for the product can be determined to maximize one or more specific criteria, such as recall, precision, F1 score, etc. As an example, for a particular product, machine learning models may be trained using an isolation forest algorithm, a kernel density estimation algorithm, and a local outlier factor algorithm. A limit for each model can be determined based on the trained machine learning model, for example, considering the shape of the failure rate curve. Prediction results of each model can be evaluated to determine various metrics, such as recall, precision, F1 score, etc. A median or average of the limits based on the models can be selected to improve one or more metrics, such as recall so that potentially defective lots are not neglected.

In this way, the limit can be dynamically determined depending on the product, available training data relating to lots, etc. Lots of the specified product having failure rates that are greater than and/or equal to the limit can be sent to hold automatically to address defects associated with the lots in real time. Causes of defects can be analyzed and addressed in production, which can lead to improved quality, savings in time and resources, etc. Outlier determination results can be incorporated into training data to improve accuracy of machine learning models. Automated workflows for detecting outliers can be implemented based on machine learning techniques to dynamically classify lots as outliers and incorporate detection results in training data to improve accuracy of the limit for determining outliers.

Detection of anomalies based on machine learning as described herein can be used in manufacturing and/or testing packaged modules, such as dual-sided modules. Examples related to upper side and/or lower side configurations of packaged modules, as well as examples related to fabrication methods where a plurality of units can be fabricated in an array format, are described in U.S. Publication No. 2022/0319968, entitled “MODULE HAVING DUAL SIDE MOLD WITH METAL POSTS,” and U.S. Publication No. 2018/0096949, entitled “DUAL-SIDED RADIO-FREQUENCY PACKAGE WITH OVERMOLD STRUCTURE,” each of which is hereby expressly incorporated by reference in its entirety. In some embodiments, at least some of the examples provided in U.S. Publication No. 2022/0319968 and U.S. Publication No. 2018/0096949 can be manufactured and/or tested using detection of anomalies based on machine learning as described herein.

In some implementations, a device and/or a circuit having or utilizing one or more features described herein can be included in an RF electronic device such as a wireless device. In some embodiments, such a wireless device can include, for example, a cellular phone, a smart-phone, a hand-held wireless device with or without phone functionality, a wireless tablet, etc.

FIG. 13 illustrates an example computing device 1300 that can be used to implement detection of anomalies based on machine learning. As illustrated, the computing device 1300 can include one or more of the following components, devices, modules, and/or units (referred to herein as “components”), either separately/individually and/or in combination/collectively: one or more processors 1350, such as central processing units (CPUs) or other type of processor, memory 1352, storage media 1354, one or more communication interfaces 1356, one or more network interfaces 1358, and/or one or more I/O components 1360.

The memory 1352 can employ a variety of storage technologies and/or form factors and can include various types of volatile memory, such as Random Access Memory (RAM). The memory 1352 can include programs that are running on the computing device 1300. The computing device 1300 may also include non-volatile memory or storage media 1354 for permanently storing data, such as important files. The storge media 1354 may include an internal storage drive, such as a solid-state drive (SSD), solid-state hybrid drive (SSHD), or hard disk drive (HDD).

The one or more communication interfaces 1356 can be a data interface that includes connectors, cables, and/or protocols for connection, communication, and/or power supply between the computing device 1300 and a data storage device, such as an external data storage device. The communication interface 1356 may include a Universal Serial Bus (USB) interface, an external Serial Advanced Technology Attachment (eSATA) interface, a Thunderbolt interface, etc. The one or more network interfaces 1358 can communicate with a network. The network may be a local area network (LAN), a wide area network (WAN) (e.g., the Internet), or other type of computer network, and the connections between the computing device 1300 and the network may be either wired or wireless. The network interface 1358 may include a network interface card, a Wi-Fi interface, etc.

The one or more I/O components 1360 can include a variety of components to receive input and/or provide output. The one or more I/O components 1360 may be configured to receive touch, speech, gesture, biometric data, or any other type of input. For example, the one or more I/O components 1360 can be used to provide input regarding control of the computing device 1300. The one or more I/O components 1360 can include a display 1362 configured to display data and various user interfaces. The display 1362 can include one or more liquid-crystal displays (LCD), light-emitting diode (LED) displays, organic LED displays, plasma displays, and/or any other type(s) of technology. In some embodiments, the display 1362 can include one or more touchscreens configured to receive input and/or display data. Further, the one or more I/O components 1360 can include one or more input/output devices 1364, which can include a touchscreen, touch pad, controller, mouse, keyboard, wearable device, etc.

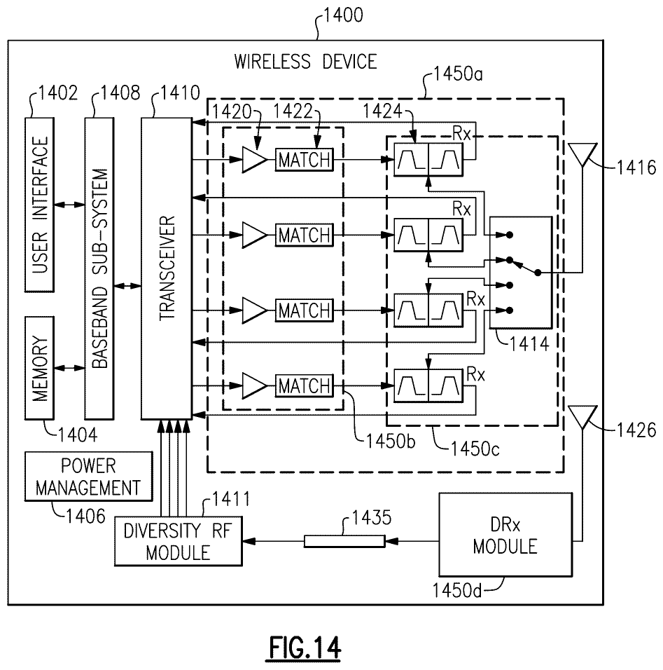

FIG. 14 depicts an example wireless device 1400 having or utilizing one or more advantageous features described herein. In the example of FIG. 14, an RF module having one or more features as described herein can be implemented in a number of places. For example, an RF module may be implemented as a front-end module (FEM) indicated as 1450a. In another example, an RF module may be implemented as a power amplifier module (PAM) indicated as 1450b. In another example, an RF module may be implemented as an antenna switch module (ASM) indicated as 1450c. In another example, an RF module may be implemented as a diversity receive (DRx) module indicated as 1450d. It will be understood that an RF module having one or more features as described herein can be implemented with other combinations of components.

Referring to FIG. 14, power amplifiers (PAS) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 can also be in communication with a power management component 1406 that is configured to manage power for the operation of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example wireless device 1400, outputs of the PAs 1420 are shown to be matched (via respective match circuits 1422) and routed to their respective duplexers 1424. Such amplified and filtered signals can be routed to a primary antenna 1416 through an antenna switch 1414 for transmission. In some embodiments, the duplexers 1424 can allow transmit and receive operations to be performed simultaneously using a common antenna (e.g., primary antenna 1416). In FIG. 14, received signals are shown to be routed to “Rx” paths that can include, for example, a low-noise amplifier (LNA).

In the example of FIG. 14, the wireless device 1400 also includes the diversity antenna 1426 and the shielded DRx module 1450d that receives signals from the diversity antenna 1426. The shielded DRx module 1450d processes the received signals and transmits the processed signals via a transmission line 1435 to a diversity RF module 1411 that further processes the signal before feeding the signal to the transceiver 1410.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A semiconductor manufacturing system comprising:
a testing system configured to test a plurality of lots of radio-frequency modules in connection with a parameter associated with a radio-frequency module, the plurality of lots of radio-frequency modules associated with a specified product; and
one or more computing devices including one or more processors, individually or in combination, configured to:
train one or more machine learning models based on training data relating to radio-frequency modules to identify a lot associated with the specified product as an anomaly in connection with the parameter;
determine a limit for detecting a lot associated with the specified product as an anomaly based on the one or more machine learning models, the limit for detecting a lot associated with the specified product as an anomaly enabling the semiconductor manufacturing system to identify one or more defective lots at an earlier point in time than using another limit associated with the specified product determined based on a statistical method, and enabling the semiconductor manufacturing system to identify one or more defective lots that do not satisfy the other limit associated with the specified product determined based on the statistical method;
determine a failure rate of a first lot in connection with the parameter;
in response to the failure rate satisfying the limit, identify the first lot as an anomaly, the first lot identified as an anomaly at an earlier point in time than using the other limit based on the statistical method, or the first lot not identified as an anomaly using the other limit based on the statistical method; and
in response to identifying the first lot as an anomaly, automatically hold the first lot in order to address defects associated with the first lot in real time, the defects not flagged using the other limit based on the statistical method.

2. The semiconductor manufacturing system of claim 1 wherein the parameter is an electrical or electromagnetic parameter associated with the radio-frequency module.

3. The semiconductor manufacturing system of claim 1 wherein the parameter includes one or more of: a radio-frequency gain, a quiescent current, an insertion loss, or a leakage current.

4. The semiconductor manufacturing system of claim 1 wherein the limit based on the one or more machine learning models is lower than the other limit associated with the specified product determined based on the statistical method, the statistical method including one or more of: six sigma, a statistical yield limit (SYL), or a statistical bin limit (SBL).

5. The semiconductor manufacturing system of claim 1 wherein the one or more processors, individually or in combination, are further configured to, in response to the failure rate not satisfying the limit, identify the first lot as normal.

6. The semiconductor manufacturing system of claim 1 wherein the one or more machine learning models are trained using one or more of: a supervised machine learning algorithm or an unsupervised machine learning algorithm.

7. The semiconductor manufacturing system of claim 1 wherein the one or more machine learning models are based on machine learning algorithms or techniques including one or more of: an isolation forest algorithm, a kernel density estimation (KDE) algorithm, a local outlier factor (LOF) algorithm, or an exponentially weighted moving average (EWMA) algorithm.

8. The semiconductor manufacturing system of claim 1 wherein the one or more machine learning models include an ensemble machine learning model trained using an isolation forest algorithm and a kernel density estimation (KDE) algorithm.

9. The semiconductor manufacturing system of claim 8 wherein the limit is based on the ensemble machine learning model.

10. The semiconductor manufacturing system of claim 1 wherein the one or more processors, individually or in combination, are further configured to:
determine one or more hyperparameter values for training a machine learning model using an isolation forest algorithm;
train a first machine learning model based on an isolation forest algorithm using training data associated with the specified product;
determine a first outlier score threshold associated with the first machine learning model, the first outlier score threshold determined based on a bottom of a failure rate curve associated with the first machine learning model before reaching the other limit based on the statistical method; and
determine a first limit based on the first machine learning model as a failure rate corresponding to the first outlier score threshold.

11. The semiconductor manufacturing system of claim 10 wherein the one or more processors, individually or in combination, are further configured to:
determine one or more hyperparameter values for training a machine learning model using a kernel density estimation (KDE) algorithm;
train a second machine learning model based on a KDE algorithm using training data associated with the specified product;
determine a second outlier score threshold associated with the second machine learning model, the second outlier score threshold determined based on a bottom of a failure rate curve associated with the second machine learning model before reaching the other limit based on the statistical method; and
determine a second limit based on the second machine learning model as a failure rate corresponding to the second outlier score threshold.

12. The semiconductor manufacturing system of claim 11 wherein the one or more processors, individually or in combination, are further configured to:
determine one or more hyperparameter values for training a machine learning model using a local outlier factor (LOF) algorithm;
train a third machine learning model based on a LOF algorithm using training data associated with the specified product;
determine a third outlier score threshold associated with the third machine learning model, the third outlier score threshold determined based on a bottom of a failure rate curve associated with the third machine learning model before reaching the other limit based on the statistical method; and
determine a third limit based on the third machine learning model as a failure rate corresponding to the third outlier score threshold.

13. The semiconductor manufacturing system of claim 12 wherein the one or more processors, individually or in combination, are further configured to determine the limit as an average or a median of the first limit based on the first machine learning model, the second limit based on the second machine learning model, and the third limit based on the third machine learning model.

14. The semiconductor manufacturing system of claim 11 wherein the one or more processors, individually or in combination, are further configured to determine the limit as an average of the first limit based on the first machine learning model and the second limit based on the second machine learning model.

15. The semiconductor manufacturing system of claim 1 wherein the one or more processors, individually or in combination, are further configured to:
determine daily mean and variance values for a failure rate associated with the specified product for a specified period of time;
train a machine learning model based on an isolation forest algorithm using the daily mean and variance values for the failure rate associated with the specified period of time;
determine daily outlier scores associated with the specified product based on the machine learning model for the specified period of time;
apply an exponentially weighted moving average to the daily outlier scores using a window of a plurality of days;
determine an outlier score threshold for the exponentially weighted moving average; and
set up an alarm that is used in response to a daily outlier score satisfying the outlier score threshold.

16. A method for testing radio-frequency modules, the method comprising:
providing a testing system configured to test a plurality of lots of radio-frequency modules in connection with a parameter associated with a radio-frequency module, the plurality of lots of radio-frequency modules associated with a specified product, the testing system included in a semiconductor manufacturing system;
training, by one or more computing devices including one or more processors, one or more machine learning models based on training data relating to radio-frequency modules to identify a lot associated with the specified product as an anomaly in connection with the parameter;
determining, by the one or more computing devices, a limit for detecting a lot associated with the specified product as an anomaly based on the one or more machine learning models, the limit for detecting a lot associated with the specified product as an anomaly enabling the semiconductor manufacturing system to identify one or more defective lots at an earlier point in time than using another limit associated with the specified product determined based on a statistical method, and enabling the semiconductor manufacturing system to identify one or more defective lots that do not satisfy the other limit associated with the specified product determined based on the statistical method;
determining, by the one or more computing devices, a failure rate of a first lot in connection with the parameter;
in response to the failure rate satisfying the limit, identifying, by the one or more computing devices, the first lot as an anomaly, the first lot identified as an anomaly at an earlier point in time than using the other limit based on the statistical method, or the first lot not identified as an anomaly using the other limit based on the statistical method; and
in response to identifying the first lot as an anomaly, automatically holding, by the one or more computing devices, the first lot in order to address defects associated with the first lot in real time, the defects not flagged using the other limit based on the statistical method.

17. The method of claim 16 further comprising:
determining, by the one or more computing devices, one or more hyperparameter values for training a machine learning model using an isolation forest algorithm;
training, by the one or more computing devices, a first machine learning model based on an isolation forest algorithm using training data associated with the specified product;
determining, by the one or more computing devices, a first outlier score threshold associated with the first machine learning model, the first outlier score threshold determined based on a bottom of a failure rate curve associated with the first machine learning model before reaching the other limit based on the statistical method; and
determining, by the one or more computing devices, a first limit based on the first machine learning model as a failure rate corresponding to the first outlier score threshold.

18. The method of claim 17 further comprising:
determining, by the one or more computing devices, one or more hyperparameter values for training a machine learning model using a kernel density estimation (KDE) algorithm;
training, by the one or more computing devices, a second machine learning model based on a KDE algorithm using training data associated with the specified product;
determining, by the one or more computing devices, a second outlier score threshold associated with the second machine learning model, the second outlier score threshold determined based on a bottom of a failure rate curve associated with the second machine learning model before reaching the other limit based on the statistical method; and
determining, by the one or more computing devices, a second limit based on the second machine learning model as a failure rate corresponding to the second outlier score threshold.

19. The method of claim 18 further comprising:
determining, by the one or more computing devices, one or more hyperparameter values for training a machine learning model using a local outlier factor (LOF) algorithm;
training, by the one or more computing devices, a third machine learning model based on a LOF algorithm using training data associated with the specified product;
determining, by the one or more computing devices, a third outlier score threshold associated with the third machine learning model, the third outlier score threshold determined based on a bottom of a failure rate curve associated with the third machine learning model before reaching the other limit based on the statistical method; and
determining, by the one or more computing devices, a third limit based on the third machine learning model as a failure rate corresponding to the third outlier score threshold.

20. The method of claim 19 further comprising determining, by the one or more computing devices, the limit as an average or a median of the first limit based on the first machine learning model, the second limit based on the second machine learning model, and the third limit based on the third machine learning model.
